(19) United States
(12) Patent Application Publication
(10) Pub. No.: US 2011/0193244 A1
(43) Pub. Date: Aug. 11, 2011

(54) ADHESIVE FILM AND PROCESS FOR PREPARING THE SAME AS WELL AS ADHESIVE SHEET AND SEMICONDUCTOR DEVICE

(76) Inventors: Takashi MASUKO, Tsukuba-shi (JP); Keisuke Ookubo, Tsukuba-shi (JP); Keiichi Hatakeyama, Tsukuba-shi (JP); Masami Yusa, Chikusei-shi (JP)

(21) Appl. No.: 13/025,783

(22) Filed: Feb. 11, 2011

Related U.S. Application Data
(62) Division of application No. 10/560,073, filed on Dec. 9, 2005.

(30) Foreign Application Priority Data
Jun. 10, 2003 (JP) P2003-164802
Jun. 11, 2003 (JP) P2003-166187

(51) Int. Cl. H01L 23/48; H01L 21/50

(52) U.S. Cl. 257/783; 438/118; 257/E21.499; 257/E23.01

(57) ABSTRACT

An object of the present invention is to provide a die-adhering adhesive film which can be laminated on a back of a wafer at a temperature lower than a softening temperature of a protecting tape for an ultra-thin wafer, or a dicing tape to be laminated, can reduce a thermal stress such as warpage of a wafer, can simplify a step of manufacturing a semiconductor device, and is excellent in heat resistance and humidity resistance reliance, an adhesive sheet in which the adhesive film and a dicing tape are laminated, as well as a semiconductor device.

### TECHNICAL FIELD

The present invention relates to a adhesive film, and a process for preparing the same, as well as an adhesive sheet and a semiconductor device.

### BACKGROUND ART

Previously, when a semiconductor chip and a semiconductor chip-carrying support member are connected, a silver paste has been mainly used. However, with recent miniaturization and high functionalization of a semiconductor chip, miniaturization and compactness have been required also for a used support member. In reply to such the demand, a silver paste has become unable to reply to the aforementioned demand due to occurrence of disadvantage at wire bonding derived from squeeze-out and inclination of a semiconductor chip, difficulty of control of a thickness of an adhesive layer, and occurrence of voids in an adhesive layer. For this reason, in order to reply to the aforementioned demand, recently, a film-like adhesive has been used (for example, see Japanese Patent Application Laid-Open (JP-A) Nos. 3-192178, 4-234472).

This adhesive film is used in a piece applying manner or a wafer back applying manner. When a semiconductor device is manufactured using the former piece applying manner adhesive film, a reel-like adhesive film is excised into pieces by cutting or punching, a piece is adhered on a support member, a semiconductor chip which has been cut into a piece by a dicing step is connected on a support member equipped with the aforementioned adhesive film, to prepare a support member equipped with a semiconductor chip and, thereafter, a semiconductor device is obtained via a wire bonding step and a sealing step (for example, see JP-A No. 9-17810). However, since an exclusive use assembling device for excising a adhesive film to adhere it to a support member is necessary in order to use the aforementioned piece applying manner adhesive film, there is a problem that the manufacturing cost becomes higher as compared with a method of using a silver paste.

On the other hand, when a semiconductor device is manufactured using a wafer back applying manner adhesive film, a adhesive film is first applied to a back of a semiconductor wafer, a dicing tape is applied to another surface of a adhesive film and, thereafter, the wafer is cut into pieces of a semiconductor chip by dicing, a piece of a semiconductor chip equipped with a adhesive film is picked up, and connected to a support member and, thereafter, a semiconductor device is obtained via steps such as heating, curing and wire bonding. Since a semiconductor chip equipped with a adhesive film is connected to a support member, this wafer back applying manner adhesive film does not need a device for excising a adhesive film into pieces and, therefore, this can be used by using the previous silver paste assembling apparatus as it is, or by improving a part of an apparatus such as addition of a platen. For this reason, this is paid an attention as a method which can reduce the manufacturing cost relatively low, among assembling methods using a adhesive film (for example, see JP-A No. 4-196246).

However, recently, in addition to the aforementioned miniaturization and thinning high functionalization of a semiconductor chip, multifunctionalization has progressed and, accompanying therewith, 3D package in which two or more semiconductor chips are laminated has been rapidly increased and, accompanying therewith, further ultra-thinning of a semiconductor wafer has being progressed. Since such the ultra-thin wafer is fragile and is easily cracked, occurrence of wafer cracking at conveyance, and wafer cracking at application of a adhesive film to a wafer back (at lamination) have become remarkable. In order to prevent this, a procedure of applying, as a protecting tape, a polyolefin-based back grind tape to the surface of a wafer has been being adopted. However, since a softening temperature of the back grind tape is 100° C. or lower, there has been strongly demanded a adhesive film which can be laminated on a back of a wafer at a temperature of 100° C. or lower.

Further, better process properties at package assembling such as pick up property after dicing, that is, easy peelability between the adhesive film and a dicing tape are required. There is an increased demand for a adhesive film which can highly realize both of such the process properties including low temperature laminating property and reliance as a package, that is, resistance to re-flowability. Previously, in order to realize both of low temperature processibility and heat resistance, there has been proposed a adhesive film in which a thermoplastic resin having relatively low Tg, and a thermosetting resin are combined (for example, see Japanese Patent No. 3014578).

### SUMMARY OF THE INVENTION

However, in order to realize both of low temperature laminating property and resistance to re-flowability, further detailed material design is necessary.

In view of the aforementioned problems, an object of the present invention is to simplify the aforementioned application step until a dicing step by provision of a wafer back application manner adhesive film which can reply to an ultra-thin wafer, and an adhesive sheet in which the adhesive film and a UV-type dicing tape are applied.

Also, an object of the present invention is to not only improve workability, but also solve the problems such as warpage of a wafer which is greatly increased in a diameter and is thinned, chip flight at dicing, and pick up property, by provision of a adhesive film which can reduce a heating temperature when a adhesive film is heated to a melting temperature, and the adhesive sheet is applied on a back of a wafer (hereinafter, referred to as laminate), below a softening temperature of the aforementioned UV-type dicing tape.

Further, an object of the present invention is to provide a adhesive film which has heat resistance and humidity resistance which are required when a semiconductor chip having a great difference in a thermal expansion coefficient is packaged on a semiconductor chip-carrying support member, and is excellent in workability and low outgassing property.

Further, an object of the present invention is to provide a semiconductor device, which can simplify a step of manufacturing a semiconductor device, and is excellent in reliance.

The present inventors intensively studied development of a die attaching film which can be laminated on a back of a wafer at a temperature lower than a softening a temperature of a protecting tape for an ultra-thin wafer, or a dicing tape to be applied, can reduce a thermal stress such as warpage of a wafer and the like, can simplify a step of manufacturing a semiconductor device, and further is excellent in heat resistance and humidity resistance reliance, and an adhesive sheet in which the aforementioned adhesive film and a UV-type dicing tape are applied, as well as a semiconductor device, which resulted in completion of the present invention.

That is, the present invention provides the following <1> to <23> adhesive films as well as adhesive sheets and semiconductor devices:

<1> A adhesive film having at least an adhesive layer, wherein the adhesive layer contains (A) a polyimide resin having a SP value of 10.0 to 11.0 (cal/cm³)^{1/2} and (B) an epoxy resin, and a tan δ peak temperature is −20 to 60° C. and a flow amount is 100 to 1500 μm.
<2> The adhesive film according to <1>, wherein the (B) epoxy resin contains a tri- or more functional epoxy resin and/or an epoxy resin which is solid at room temperature.
<3> The adhesive film according to <1>, wherein the (B) epoxy resin contains 10 to 90% by weight of a tri- or more functional epoxy resin, and 10 to 90% by weight of an epoxy resin which is liquid at room temperature.
<4> The adhesive film according to any one of <1> to <3>, wherein 1 to 50 parts by weight of the (B) epoxy resin is contained relative to 100 parts by weight of the (A) polyimide resin.
<5> The adhesive film according to any one of <1> to <5>, wherein as the (A) polyimide resin, a polyimide resin obtained by reacting an acid dianhydride satisfying the condition where a difference between a heat generation initiating temperature and a heat generation peak temperature is 10° C. or smaller, and diamine is contained at 50% by weight or more of a total polyimide resin.
<6> The adhesive film according to any one of <1> to <5>, wherein (C) an epoxy resin curing agent is further contained.
<7> The adhesive film according to <6>, wherein the (C) epoxy resin curing agent is a phenol-based compound having 2 or more hydroxy groups in a molecule and having a number average molecular weight of 400 to 1500.
<8> The adhesive film according to <6>, wherein the (C) epoxy resin curing agent is a naphthol-based compound having 3 or more aromatic rings in a molecule or a trisphenol-based compound.
<9> The adhesive film according to <7> or <8>, wherein an equivalent ratio of an epoxy equivalent of the (B) epoxy resin and an OH equivalent of the (C) epoxy resin curing agent is 0.95 to 1.05:0.95 to 1.05.
<10> The adhesive film according to any one of <1> to <9>, wherein the (A) polyimide resin is a polyimide resin obtained by reacting a tetracarboxylic acid dianhydride, and diamine containing 1% by mol or more of total diamine of aliphatic etherdiamine represented by the following formula (I):

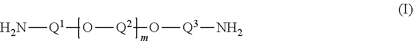

(wherein Q¹, Q² and Q³ each represent independently an alkylene group having 1 to 10 carbon atoms, and m represents an integer of 2 to 80).
<11> The adhesive film according to any one of <1> to <9>, wherein the (A) polyimide resin is a polyimide resin obtained by reacting a tetracarboxylic acid dianhydride, and diamine containing 1 to 90% by mol of total diamine of aliphatic etherdiamine represented by the following formula (I):

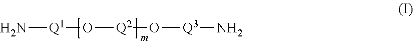

(wherein Q¹, Q² and Q³ each represent independently an alkylene group having 1 to 10 carbon atoms, and m represents an integer of 2 to 80),
0 to 99% by mol of total diamine of aliphatic diamine represented by the following general formula (II):

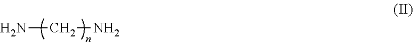

(wherein n represents an integer of 5 to 20),
and 0 to 99% by mol of total diamine of siloxanediamine represented by the following general formula (III):

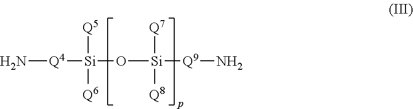

(wherein Q⁴ and Q⁹ each represent independently an alkylene group having 1 to 5 carbon atoms or an optionally substituted phenylene group, Q⁵, Q⁶, Q⁷ and Q⁸ each represent independently an alkyl group having 1 to 5 carbon atoms, a phenyl group or a phenoxy group, and p represents an integer of 1 to 5).
<12> The adhesive film according to any one of <1> to <11>, wherein the (A) polyimide resin is a polyimide resin obtained by reacting a tetracarboxylic acid dianhydride containing 50% by mol or more of total tetracarboxylic acid dianhydride of tetracarboxylic acid dianhydride containing no ester linkage, and diamine.
<13> The adhesive film according to <12>, wherein the tetracarboxylic acid dianhydride containing no ester linkage is tetracarboxylic acid dianhydride represented by the following general formula (IV):

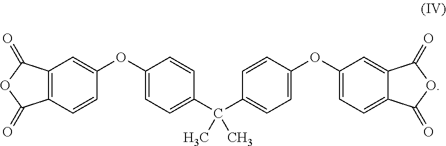

<14> The adhesive film according to any one of <2> to <13>, wherein the tri- or more functional epoxy resin is a novolak-type epoxy resin represented by the following general formula (VII):

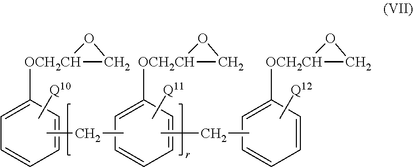

(wherein Q¹⁰, Q¹¹ and Q¹² each represent independently hydrogen, an alkylene group having 1 to 5 carbon atoms, or an optionally substituted phenylene group, and r represents an integer of 1 to 20).
<15> The adhesive film according to any one of <1> to <14>, which further contains (D) filler.
<16> The adhesive film according to <15>, wherein the (D) filler is an insulating filler.
<17> The adhesive film according to <15> or <16>, wherein an average particle diameter of the (D) filler is 10 μm or smaller, and a maximum particle diameter of the (D) filler is 25 μm or smaller.
<18> The adhesive film according to any one of <15> to <17>, wherein a content of the (D) filler is 1 to 50% by volume.
<19> The adhesive film according to any one of <1> to <18>, wherein a difference between surface energy of the adhesive film and surface energy of an organic substrate equipped with a solder resist material is 10 mN/m or smaller.
<20> The adhesive film according to any one of <1> to <19>, wherein at a stage where the adhesive is laminated on a silicon wafer at 80° C., a 90° peeling force at 25° C. to the silicon wafer is 5N/m or larger.
<21> An adhesive sheet characterized in that a substrate layer, a self-adhesive layer, and the adhesive film layer as claimed in any one of <1> to <20> are formed in this order.
<22> The adhesive sheet according to <21>, wherein the self-adhesive layer is a radiation curing-type self-adhesive layer.
<23> A semiconductor devise having a structure in which at least one of (1) a semiconductor chip and a semiconductor chip-carrying support member, and (2) semiconductor chips are adhered via the adhesive film as claimed in any one of <1> to <20>.

The present application claims priority based on Japanese Patent Applications previously filed by the same applicant, that is, No. 2003-164802 (filed on Jun. 10, 2003) and No. 2003-166187 (filed on Jun. 11, 2003), the specifications thereof are incorporated herein by reference.

### BRIEF DESCRIPTION OF THE DRAWINGS

FIG. 1 is a view showing one example of a laminating method according to the present invention.

FIG. 2 is a view showing one example of a laminating method according to the present invention.

FIG. 3 is a view showing one example of a method of measuring a 90° peeling force to a silicon wafer.

FIG. 4 is a view showing one example of a method of measuring a 90° peeling force to a dicing tape.

FIG. 5 is a view showing one example of a semiconductor device having a general structure.

FIG. 6 is a view showing one example of a semiconductor device having a structure in which semiconductor chips are adhered.

FIG. 7 is a cross-sectional view of a monolayer adhesive film composed only of an adhesive layer 15.

FIG. 8 is a cross-sectional view of a adhesive film in which an adhesive layer 15 is disposed on both sides of a substrate film 16.

FIG. 9 is a cross-sectional view of a adhesive film provided with a substrate film 17, an adhesive layer 18 and a cover film 19.

FIG. 10 is a view showing a peeling strength measuring method using a push-pull gauge.

FIG. 11 is a view showing relationship between a kind of a main chain skeleton of polyimide and a flow amount.

### DETAILED DESCRIPTION OF THE PRESENT INVENTION

The adhesive film of the present invention contains (A) a thermoplastic resin and (B) an epoxy resin as essential components, can be laminated on a back of a wafer at a temperature lower than a softening temperature of a protecting tape for an ultra-thin wafer, or dicing tape to be applied, can maintain better pick up property with a dicing tape after dicing, and has excellent heat resistance and humidity resistance reliance.

### (A) Thermoplastic Resin

The (A) thermoplastic resin is at least one resin selected from the group consisting of a polyimide resin, a polyetherimide resin, a polyesterimide, a polyamide resin, a polyester resin, a polysulfone resin, a polyethersulfone resin, a polyphenylene sulfide resin, a polyetherketone resin and a phenoxy resin. Inter alia, a polyimide resin and a polyetherimide resin are preferable.

The polyimide resin can be obtained, for example, by condensation-reacting tetracarboxylic acid dianhydride and diamine by the known method. That is, equivalent mols or approximately equivalent mols of tetracarboxylic acid dianhydride and diamine are used (order of addition of respective components is arbitrary) to perform an additional reaction at a reaction temperature of 80° C. or lower, preferably 0 to 60° C. in an organic solvent. As a reaction progresses, a viscosity of a reaction solution is gradually increased, and polyamidic acid, which is a precursor of polyimide, is produced.

A molecular weight of the polyamidic acid may be adjusted by depolymerization by heating at a temperature of 50 to 80° C. The polyimide resin can be obtained by dehydration ring closing of the aforementioned reaction product (polyamidic acid). Dehydration ring closing can be performed by a thermal ring closing method in which heating treatment is performed, or a chemical ring closing method in which a dehydrating agent is used.

Tetracarboxylic acid dianhydride used as a raw material of the polyimide resin is not particularly limited, but examples thereof include pyromellitic acid dianhydride, 3,3′,4,4′-biphenyltetracarboxylic acid dianhydride, 2,2′,3,3′-biphenyltetracarboxylic acid dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl)ether dianhydride, benzene-1,2,3,4-tetracarboxylic acid dianhydride, 3,4,3′,4′-benzophenonetetracarboxylic acid dianhydride, 2,3,2′,3′-benzophenonetetracarboxylic acid dianhydride, 3,3,3′,4′-benzophenonetetracarboxylic acid dianhydride, 1,2,5,6-naphthalenetetracarboxylic acid dianhydride, 1,4,5,8-naphthalenetetracarboxylic acid dianhydride, 2,3,6,7-naphthalenetetracarboxylic acid dianhydride, 1,2,4,5-naphthalenetetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,5,6-tetracarbocylic acid dianhydride, 2,3,3′,4′-biphenyltetracarboxylic acid dianhydride, 3,4,3′,4′-biphenyltetracarboxylic acid dianhydride, 2,3,2′, 3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutanetetracarboxylic acid dianhydride, bis(exo-bicyclo[2,2,1]heptene-2,3-dicarboxylic acid dianhydride, bicyclo-[2,2,2]-oct-7-ene-2,3,5,6-tetracarboxylic acid dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4′-bis(3,4-dicarboxyphenoxy)diphenyl sulfide dianhydride, 1,4-bis(2-hydroxyhexafluoroisopropyl)benzenebis(trimellitic anhydride), 1,3-bis(2-hydroxyhexafluoroisopropyl)benzenebis(trimellitic anhydride), 5-(2,5-dioxotetrahydrofuryl)-3-methyl-3-cyclohexene-1,2-dicarboxylic acid dianhydride, terahydrofuran-2,3,4,5-tetracarboxylic acid dianhydride, tetracarboxylic acid dianhydride represented by the following general formula (IX):

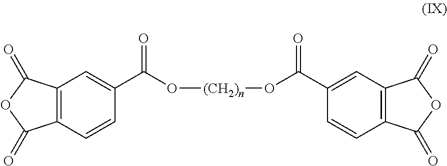

(wherein n represents an integer of 2 to 20),
tetracarboxylic acid dianhydride represented by the following formula (IV):

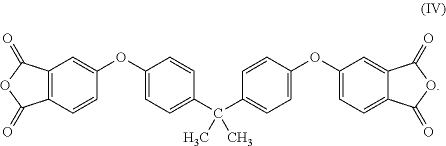

Tetracarboxylic acid dianhydride represented by the above general formula (IX) can be synthesized, for example, from trimellitic acid anhydride monochloride and corresponding diol and specific examples thereof include 1,2-(ethylene)bis(trimellitate anhydride), 1,3-(trimethylene)bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene)bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride), and 1,18-(octadecamethylene)bis(trimellitate anhydride). Inter alia, from a view point of impartation of excellent humidity resistance reliance, tetracarboxylic acid dianhydride represented by the above formula (IV) is preferable. These tetracarboxylic acid dianhydrides can be used alone, or by combining two or more.

In addition, tetracarboxylic acid dianhydride represented by the above general formula (IV) is a preferable representative example of tetracarboxylic acid dianhydride containing no ester linkage and, by using such the tetracarboxylic acid dianhydride, humidity resistance reliance of a adhesive film can be improved. A content thereof is preferably 40% by mol or more, more preferably 50% by mol or more, extremely preferably 70% by mol or more relative to total tetracarboxylic acid dianhydride. When the content is smaller than 40% by mol, effect of humidity resistance reliance due to use of tetracarboxylic acid dianhydride represented by the above formula (IV) can not be sufficiently maintained.

It is preferable to use the aforementioned acid dianhydrides, which are purified by recrystallization with acetic anhydride in that both of suitable flowability and high efficacy of a curing reaction can be realized. Specifically, acid dianhydrides are purification-treated so that a difference between a heat generation initiating temperature and a heat generation peak temperature by means of DSC becomes 10° C. or smaller. A content of a polyimide resin synthesized using acid dianhydride with purity enhanced by this treatment is 50 wt % or larger of a total polyimide resin. When the content is 50 wt % or larger, various properties (in particular, adherability and re-flow crack resistance) of a adhesive film can be improved, being preferable.

Diamine used as a raw material of the polyimide resin is not particularly limited, but examples thereof include aromatic diamines such o-phenylenediamine, m-phenylene diamine, p-phenylenediamine, 3,3′-diaminodiphenylether, 3,4′-diaminodiphenylether, 4,4′-diaminodiphenylether, 3,3′-diaminodiphenylmethane, 3,4′-diaminodiphenylmethane, 4,4′-diaminodiphenylether methane, bis(4-amino-3,5-dimethylphenyl)methane, bis(4-amino-3,5-diisopropylphenyl)methane, 3,3′-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenyl sulfide, 3,4′-diaminophenyl sulfide, 4,4′-diaminodiphenyl sulfide, 3,3′-diaminodiphenyl ketone, 3,4′-diaminodiphenyl ketone, 4,4′-diaminodiphenyl ketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminophenoxy)phenyl)sulfide, bis(4-(4-aminophenoxy)phenyl)sulfide, bis(4-(3-aminophenoxy)phenyl)sulfone, bis(4-(4-aminophenoxy)phenyl)sulfone, 3,5-diaminobenzoic acid and the like, 1,3-bis(aminomethyl)cyclohexane, 2,2-bis(4-aminophenoxyphenyl)propane, aliphatic etherdiamine represented by the following formula (I):

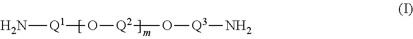

(wherein Q¹, Q² and Q³ each represent independently an alkylene group having 1 to 10 carbon atoms, and m represents an integer of 2 to 80),
aliphatic diamine represented by the following general formula (II):

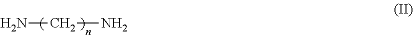

(wherein n represents an integer of 5 to 20), and siloxanediamine represented by the following general formula (III):

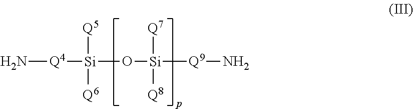

(wherein Q⁴ and Q⁹ each represent independently an alkylene group having 1 to 5 carbon atoms or an optionally substituted phenylene group, Q⁵, Q⁶, Q⁷ and Q⁸ each represent independently an alkyl group having 1 to 5 carbon atoms, a phenyl group or a phenoxy group, and p represents an integer of 1 to 5).
Inter aria, the above general formula (I) is preferable in that low stress property, low temperature laminating property, low temperature adherability, and high adherability with an organic substrate equipped with a resist material can be imparted, and suitable flowability at heating can be maintained. In this case, 1% by mol or more of total diamine is preferable, 5% by more or more is more preferable, and 10% by mol or more is further preferable. Smaller than 1% by mol is not preferable because the aforementioned properties can not be imparted.

In addition, in addition to the above general formula (I), a combination of the above general formula (II) and/or and (III) is preferable that reactivity with acid dianhydride can be maintained and low water absorbability and low hygroscopicity can be imparted. In this case, it is preferable that aliphatic etherdiamine represented by the general formula (I) is 1 to 90% by mol of total diamine, aliphatic diamine represented by the general formula (II) is 0 to 99% by mol of total diamine, or siloxanediamine represented by the following general formula (III) is 0 to 99% by mol of total diamine. More preferably, aliphatic etherdiamine represented by general formula (I) is 1 to 50% by mol of total diamine, aliphatic diamine represented by the general formula (II) is 20 to 80% by mol of total diamine, or siloxanediamine represented by the following general formula (III) is 20 to 80% by mol of total diamine. Outside the aforementioned % by mol range, effect of impartation of low temperature laminating property and low water absorbability becomes small, being not preferable.

In addition, specific examples of aliphatic etherdiamine represented by the above general formula (I) include:

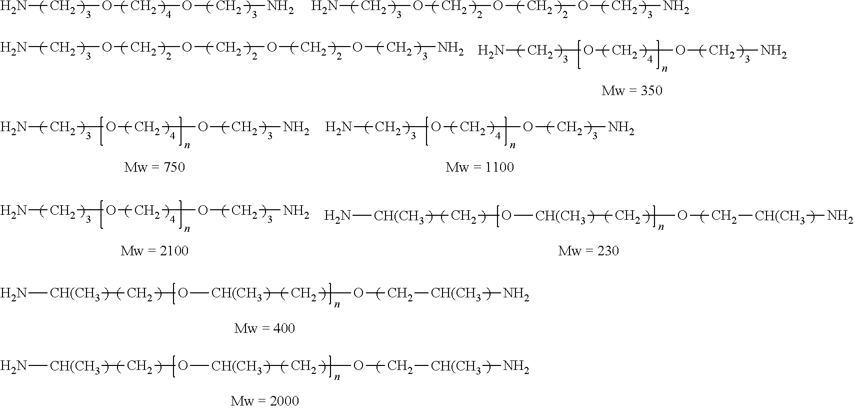

Inter alia, aliphatic etherdiamine represented by the following formula (V):

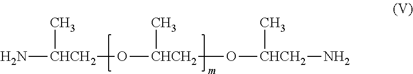

(wherein m represents an integer 2 to 80)
is more preferable in that low temperature laminating property and better adherability with a substrate equipped with an organic resist can be maintained. Specific examples thereof include aliphatic diamines such as polyoxyalkylenediamine such as Gefermin D-230, D-400, D-2000, D-4000, ED-600, ED-900, ED-2001, EDR-148 (foregoing are trade names manufactured by Sun Technochemical (K.K.)). Polyetheramine D-230, D-400, D-2000 (foregoing are trade names manufactured by BASF) and the like.

Examples of aliphatic diamine represented by the above general formula (II) include 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,11-diaminoundecane, 1,12-diaminododecane, 1,2-diaminocyclohexane and the like and, inter alia, 1,9-diaminononane, 1,10-diaminodecane, 1,11-diaminoundecane, and 1,12-diaminododecane are preferable.

In addition, as siloxanediamine represented by the above general formula (III), for example, among the above formula (III), <when p is 1>, there are 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, 1,3-dimethyl-1,3-dimethoxy-1,3-bis(4-aminobutyl)disiloxane and the like, <when p is 2>, there are 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, 1,1,3,3,5,5-hexapropyl-1,5-bis(3-aminopropyl)trisiloxane and the like.

The above polyimide resins may be used alone, or by mixing (blending) two or more as necessary.

A temperature at which the adhesive film of the present invention can be laminated is preferably a heat resistant or softening temperature of a protecting tape for a wafer, that is, a back grind tape, or lower, or a heat resistant or softening temperature of a dicing tape, or lower and, also from a viewpoint that warpage of a semiconductor wafer is suppressed, is preferably 10 to 80° C., more preferably 10 to 60° C., further preferably 10 to 40° C. In order to attain the aforementioned laminating temperature, Tg of the polyimide resin is preferably −20 to 60° C., more preferably −10 to 40° C. When the Tg exceeds 60° C., a possibility that the laminating temperature exceeds 80° C. tends to be higher. In addition, upon determination of a composition of polyimide, it is preferable that its Tg is −20 to 60° C.

In addition, a weight average molecular weight of the polyimide resin is controlled in a range of preferably 10,000 to 200,000, more preferably 10,000 to 100,000, extremely preferably 10,000 to 80,000. When the weight average molecular weight is smaller than 10,000, film forming property is deteriorated, and strength of a film becomes small. When the weight average molecular weight exceeds 200,000, flowability at heating becomes deteriorated, and embedding property in irregularities on a substrate is reduced. Both cases are not preferable.

By rendering Tg and a weight average molecular weight of the polyimide in the aforementioned range, not only a laminating temperature can be suppressed below, but also a heating temperature (die bonding temperature) when a semiconductor chip is adhered and fixed to a semiconductor chip-carrying support member can be also reduced, and increase in warpage of a chip can be suppressed. The aforementioned Tg is Tg measured under conditions of a sample amount of 10 mg, a temperature rising rate of 5° C./rain, and measuring atmosphere: air, using DSC (DSC-7 Model manufactured by Perkin Elmer). In addition, the aforementioned weight average molecular weight is a weight average molecular weight when synthetic polyimide is measured in terms of polystyrene, using high speed liquid chromatography (C-R4A manufactured by Shimadzu Corporation).

In addition, it is preferable that a SP value (solubility parameter) of the polyimide resin is controlled in a range of 10.0 to 11.0 (cal/cm³)^{1/2}. When the SP value is smaller than 10.0, an intramolecular cohesive force is small, and hot flowability of a adhesive film on a B stage becomes greater than required, or the adhesive progresses toward low polarity or hydrophobicity and, therefore, surface energy of a adhesive film becomes small, and a difference between surface energy (around 40 mN/m) of a resist material on a substrate becomes great and, as a result, adherability with the substrate is deteriorated, being not preferable. When the SP value is greater than 11.0, water absorption of a adhesive film is increased accompanied with hydrophilization, being not preferable. The SP value is calculated by the following equation.

SP value(Δ)=ΣΔF/ΣΔν

ΣΔF is a sum of mol attraction force constant of various atoms or various atom moieties at 25° C., ΣΔν is a sum of mol volume of various atoms or various atom moieties and, as values of ΔF and Δν of various atoms or various atom moieties, Okitsu constants (author: Toshinao Okitsu, “Adhesion”, vol. 40, No. 8, P 342 (1996)) described in the following Table 1 were used.

TABLE 1
ΔF and Δν of various atom moieties

| | Okitsu's | | | Okitsu's | | | Okitsu's | |
|---|---|---|---|---|---|---|---|---|
| Groups | ΔF | Δν | Groups | ΔF | Δν | Groups | ΔF | Δν |
| —CH [symbol] | 205 | 31.8 | —OH (Diol) | 270 | 12.0 | —SH | 310 | 28.0 |
| —CH [symbol] — | 132 | 16.5 | —OH(Arom) | 238 | 12.0 | >SO₃ | 675 | 11.4 |
| >CH— | 28.6 | −1.0 | —NH₂ | 273 | 16.5 | >S═O | 485 | 11.4 |
| >CH— (Poly) | 28.6 | 1.9 | —NH₂(Arom) | 238 | 21.0 | —S— | 201 | 12.0 |
| >C< | −81 | 14.8 | —NH— | 180 | 8.5 | S═ | 201 | 23.0 |
| >C<(Poly) | −81 | 19.2 | —NH— (Link) | 180 | 4.0 | SO [symbol] | 322 | 27.5 |
| CH [symbol] ═ | 195 | 31.0 | —N< | 61.0 | −9.0 | SO [symbol] | 465 | 31.8 |
| —CK═ | 116 | 13.7 | —N═ | 118 | 5.0 | >Si< | 16.3 | 0 |
| >C═ | 24.2 | −2.4 | —N═ (Link) | 118 | 15.0 | PO [symbol] | 374 | 28.0 |
| ═C═ | 200 | 25.0 | —CN | 420 | 23.0 | H | 81 | 8.0 |
| —C═ | 100 | 6.5 | —CN(Arom) | 252 | 27.0 | —C [symbol] H [symbol] (Arom) | 731 | 72.0 |
| —O— | 120 | 5.1 | —CN(Poly) | 420 | 27.0 | —C [symbol] H [symbol] (Arom) | 655 | 62.0 |
| —O— (Arom, Lin) | 70 | 3.8 | —NO [symbol] | 481 | 24.0 | —C [symbol] H [symbol] (Arom) | 550 | 39.0 |
| —O— (Epoxy) | 176 | 5.1 | —NO [symbol] (Arom) | 342 | 32.0 | —C [symbol] H [symbol] (Arom) | 450 | 27.0 |
| —CO— | 286 | 10.0 | —NCO | 498 | 35.0 | —C [symbol] H [symbol] (Poly) | 731 | 79.0 |
| —COOH | 373 | 24.4 | —NHCO— | 690 | 18.5 | —C [symbol] H [symbol] (Poly) | 655 | 69.0 |
| —COOH(Arom) | 242 | 24.4 | >NHCO— | 441 | 5.4 | —C [symbol] H [symbol] (Poly) | 550 | 47.0 |
| —COO— | 353 | 19.6 | —CL(Mono) | 330 | 23.0 | —C [symbol] H [symbol] (Poly) | 450 | 32.0 |
| —COO— (Poly) | 330 | 22.0 | —CL(Di) | 250 | 25.0 | — (Cyclohexyl) | 790 | 97.5 |
| —O—CO—O— | 526 | 20.0 | —CL(Tri, Tetra) | 235 | 27.0 | (Plus onto upper groups) | | |
| —CHO | 370 | 25.0 | —CL(Arom) | 235 | 27.0 | 3 Member 1 in | +110 | +18 |
| —CHO(Arom) | 213 | 29.0 | —CL(>C<) | 235 | 28.0 | 4 Member 1 in | +110 | +18 |
| —OH(Mono) | 395 | 10.0 | —CL(Poly) | 270 | 27.0 | 5 Member 1 in | +110 | +16 |
| —OH(Ether) | 342 | 12.0 | —Br(mean) | 302 | 30.0 | 6 Member 1 in | +100 | +16 |
| —OH(H₂O) | 342 | 12.0 | —F(mean) | 130 | 19.0 | Conjugated | +30 | −22 |
| | | | | | | Double bond | | |
| —OH(Poly) | 282 | 17.0 | —F(Poly) | 110 | 21.0 | Conjugated | +30 | −10 |
| | | | | | | Double bond(Link) | | |

Note:
(Poly) = Polymer; (Arom) = Aromatic; (Lin) = Link [symbol]
indicates data missing or illegible when filed

The SP value can be controlled by changing the concentration of an imido group of polyimide, or the concentration of a polar group in a polyimide main chain skeleton. The concentration of an imido group of polyimide is controlled by a distance between imido groups. For example, when a distance between imido groups is increased by introducing a long chain alkylene linkage, or a long chain siloxane linkage into a main chain of polyimide, the concentration of an imido group is decreased. In addition, since the aforementioned linkages have relatively low polarity, when a skeleton containing these linkages is selected and introduced, the concentration of a polar group of a whole structure becomes low. As a result, a SP value of polyimide progresses toward lower. On the other hand, by the reverse procedure, that is, by decreasing a distance between imido groups, or by selecting and introducing a skeleton containing a highly polar linkage such as an ether linkage into a main chain, a SP value of polyimide progresses toward higher. Like this, a SP value of polyimide to be used is adjusted in a range of 10.0 to 11.0.

In order to reduce Tg of polyimide, it is usually contemplated a procedure of introducing a long chain siloxane linkage, a long chain aliphatic ether linkage, a long chain methylene linkage or the like into a main chain skeleton to obtain a soft structure of a polyimide main chain.

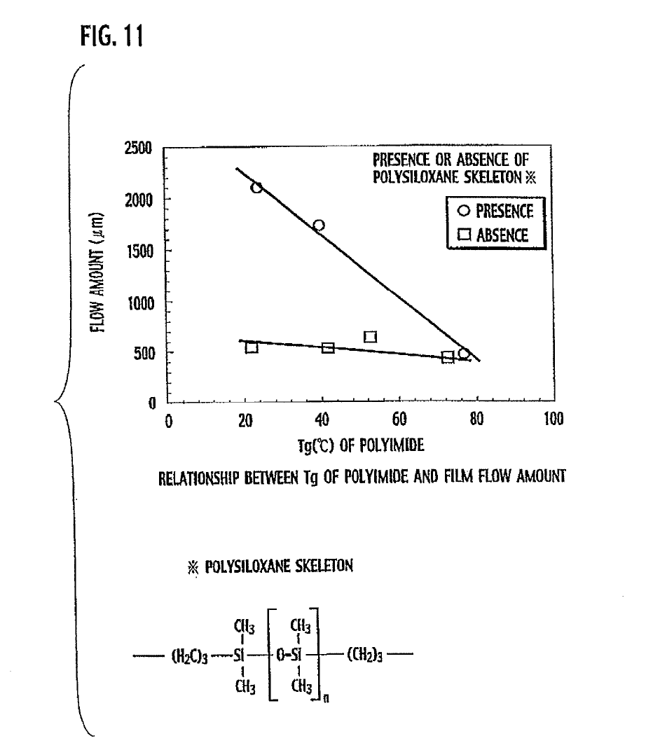

In addition, relationship between a kind of a main chain structure of polyimide and a flow amount was studied and, as a result, it was found that a film using polyimide with a long chain siloxane linkage introduced therein has a tendency that it has a higher flow amount than that of a film having no this skeleton (FIG. 11). It is considered that this is caused by a difference in Tg of a skeleton itself and this is because, among the aforementioned long chain skeletons, Tg of a siloxane skeleton is lowest, and a siloxane skeleton is softest. By adjusting Tg of an introduced skeleton and a length of a skeleton like this, a flow amount of a film can be controlled. In addition, since a flow amount of a film progresses toward larger by introducing a liquid epoxy resin having a low viscosity at a normal temperature into a film composition, a flow amount of a film can be controlled by adjusting an amount of the epoxy resin to be introduced.

Based on the aforementioned findings, as a procedure of reducing a tan δ peak temperature of a film without decreasing a SP value of polyimide, a long chain aliphatic ether skeleton containing an ether linkage having relatively high polarity is selected and introduced into a main chain of polyimide to be used, and Tg of polyimide is reduced while decrease in a SP value of polyimide to be used is suppressed. Thereby, a tan δ peak temperature of a film can be effectively lowered. In addition, since introduction of a liquid epoxy resin having a low viscosity at a normal temperature into a film composition can effectively lower a tan δ peak temperature of a film, this is effective as a procedure of taking balance between a SP value of polyimide to be used and a tan δ peak temperature of a film. Like this, a material is designed so that a SP value of polyimide can be controlled in a range of 10.0 to 11.0 (cal/cm³)^{1/2}, a flow amount can be controlled in a range of 100 to 1500 μm, and a tan δ peak temperature around Tg of a film can be controlled in a range of −20 to 60° C.

### (B) Epoxy Resin

The (B) epoxy resin used in the present invention is not particularly limited, but it is preferable that a tri- or more functional epoxy resin and/or an epoxy resin, which is solid at room temperature, are contained.

In the present invention, a content of the (B) epoxy resin is 1 to 50 parts by weight, preferably 1 to 40 parts by weight, more preferably 5 to 20 parts by weight relative to 100 parts by weight of the (A) polyimide. When the content is smaller than 1 part by weight, bridging effect due to a reaction with a polyimide resin is not obtained and, when the content exceeds 50 parts by weight, contamination of a semiconductor chip or a device with outgassing at heating is worried about, being not preferable.

When a flow amount of a adhesive film is reduced due to use of a tri- or more functional epoxy resin, it is preferable to use a liquid epoxy resin jointly in order to adjust this. In this case, an amount to be incorporated is preferably such that a tri- or more functional epoxy resin is contained at 10 to 90% by weight of a total epoxy resin, and a liquid epoxy resin is contained at 10 to 90% by weight of a total epoxy resin. For example, when (B1) a tri- or more functional solid epoxy resin, (B2) a tri- or more functional liquid epoxy resin, and (B3) a bifunctional liquid epoxy resin are used jointly, a sum of (B1) and (B2) (i.e. sum of tri- or more functional epoxy resins) is 10 to 90% by weight, and a sum of (B2) and (B3) (i.e. sum of liquid epoxy resins) is 10 to 90% by weight. In addition, an incorporation amount of the (B1) tri- or more functional epoxy resin relative to a total epoxy resin is more preferably 10 to 80% by weight, particularly preferably 10 to 70% by weight, extremely preferably 10 to 60% by weight. When the amount is smaller than 10% by weight, there is a tendency that a crosslinking density of a cured product can not be effectively increased and, when the amount exceeds 90% by weight, there is a tendency that flowability at heating before curing can not be sufficiently obtained.

In addition, when a tri- or more functional epoxy resin is used as the (B) epoxy resin, it is preferable that a tri- or more functional epoxy resin is contained at 5 to 30 parts by weight, and a liquid epoxy resin is contained at 10 to 50 parts by weight relative to 100 parts by weight of the (A) polyimide resin, in that better reliance as a package, such as a laminating temperature of 25 to 100° C., low outgassing property at assembling heating, resistance to re-flowability, and humidity resistance reliance and the like can be maintained at the same time.

The tri- or more functional epoxy resin is not particularly limited as far as it contains at least 3 or more epoxy groups in a molecule, but examples of such the epoxy resin include trifunctional (or tetrafunctional) glycidyl ether, trifunctional (or tetrafunctional) glycidylamine and the like, in addition to a nobolak-type epoxy resin represented by the following general formula (VII);

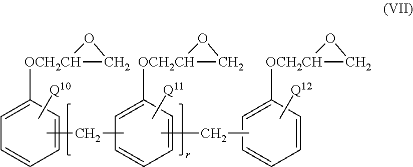

(wherein and Q¹⁰, Q¹¹ and Q¹² each represent independently hydrogen, an alkylene group having 1 to 5 carbon atoms, or an optionally substituted phenylene group, and r represents an integer of 1 to 20). Examples of the novolak-type epoxy resin represented by the above general formula (VII) include glycidyl ether of a cresol novolak resin, glyciyl ether of a phenol novolak resin and the like. Inter alia, a novolak-type epoxy resin represented by the above general formula (VII) is preferable in that a crosslinking density of a cured product is high, and an adhesion strength of a film at heating can be increased. These may be used alone, or by combining two or more.

In addition, the liquid epoxy resin is an epoxy resin, which has two or more epoxy groups in a molecule and is liquid at 10 to 30° C., and the liquid includes the state of a viscous liquid. The solid means solid at room temperature, and means solid at 10 to 30° C., a temperature being not particularly limited.

Examples of the liquid epoxy resin include a bisphenol-type epoxy resin represented by the following general formula (VIII):

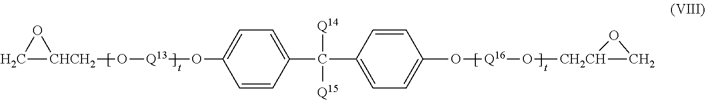

(wherein Q¹³ and Q¹⁶ represent independently an alkylene group having 1 to 5 carbon atoms, or an optionally substituted phenylene group or phenoxy group, Q¹⁴ and Q¹⁵ represent independently an alkyl group having 1 to 5 carbon atoms, or hydrogen, and t represents an integer of 1 to 10),
in addition to glycidyl ether of bisphenol A type (or AD type, S type, F type), glycidyl ether of hydrogenated bisphenol A type, glycidyl ether of a phenol novolak resin, glycidyl ether of cresol novolak resin, glycidyl ether of a bisphenol A novolak resin, glycidyl ether of a napththalene resin, trifunctional (or tetrafunctional) glycidyl ether, glycidyl ether of a dicyclopentadienephenol resin, glycidyl ester of dimer acid, trifunctional (or tetrafunctional) glycidylamine, glycidylamine of a naphthalene resin and the like.

Examples of the epoxy resin represented by the above general formula (VIII) include glycidyl ether of ethylene oxide-added bisphenol A type, glycidyl ether of propylene oxide-added bisphenol A type and the like. An epoxy resin which is liquid at 10 to 30° C. is selected from them.

When the liquid epoxy resin is selected, it is preferable to select a liquid epoxy resin having a number average molecular weight in a range of 400 to 1500. Thereby, outgassing which causes pollution of the surface of a chip or an apparatus at package assembling heating, can be effectively reduced. A bisphenol-type epoxy resin represented by the general formula (VIII) is preferable in that better heating flowability of a film can be maintained, low temperature laminating property can be imparted, and the aforementioned outgassing can be reduced.

The adhesive film of the present invention may further contain (C) an epoxy resin curing agent. The (C) epoxy resin curing agent is not particularly limited, but examples thereof include phenol-based compound, aliphatic amine, alicyclic amine, aromatic polyamine, polyamide, aliphatic acid anhydride, alicyclic acid anhydride, aromatic acid anhydride, dicyandiamide, organic acid dihydrazide, boron trifluoride amine complex, imidazoles, tertiary amine and the like. Inter alia, a phenol-based compound is preferable, and a phenol-based compound having at least two phenolic hydroxyl groups in a molecule is more preferable.

Examples of the phenol-based compound having at least two phenolic hydroxyl groups in a molecule include a phenol novolak resin, a cresol novolak resin, a t-butylphenol novolak resin, a dicyclopentadienecresol novolak resin, a dicyclopentadienephenol novolak resin, a xylilene-modified phenol novolak resin, a naphthol novolak resin, a trisphenol novolak resin, a tetrakisphenol novolak resin, a bisphenol A novolak resin, a poly-p-vinylphenol resin, a phenolaralkyl resin and the like. Among them, resins having a number average molecular weight in a range of 400 to 1500 are preferable. Thereby, outgassing which causes pollution of the surface of a chip or an apparatus at package assembling heating, can be effectively reduced. Inter alia, a naphthol novolak resin, and a trisphenol novolak resin are preferable in that outgassing which causes pollution of the surface of a chip or an apparatus, or odor at package assembling heating can be effectively reduced.

The naphthol novolak resin is a naphthol-based compound having 3 or more aromatic rings in a molecule, represented by the following general formula (XI) or the following general formula (XII).

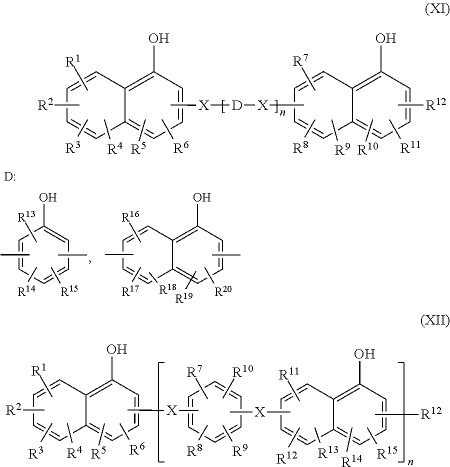

In the above formulas (XI) and (XII), R¹ to R²⁰ each represent independently hydrogen, an alkyl group having 1 to 10 carbon atoms, a phenyl group or a hydroxyl group, and n represents an integer of 1 to 10. And, X is a divalent organic group, and examples thereof include the following groups.

### X:

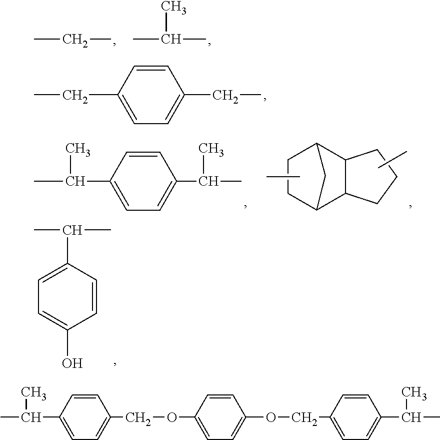

More specific examples of such the naphthol-based compound include xylilene-modified naphthol novolak represented by the following general formula (XIII) and (XIV), and naphthol novolak fused with p-cresol represented by the following general formula (XV).

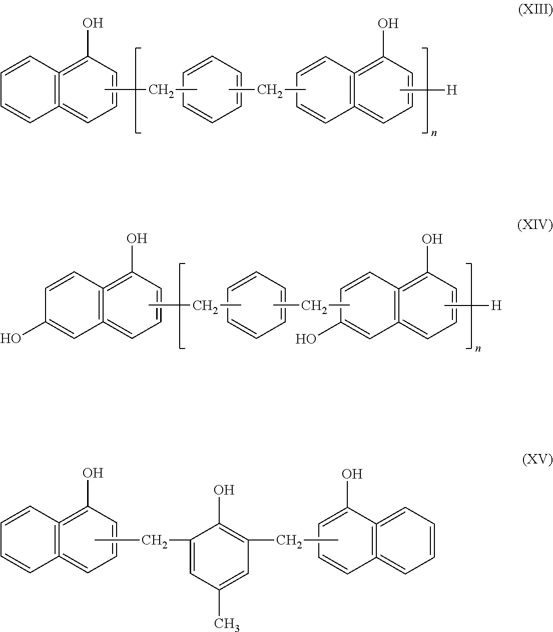

In the above general formulas (XIII) and (XIV), a repeating number (n) is preferably 1 to 10.

The trisphenol-based compound is a trisphenol novolak resin having 3 hydroxyphenyl groups in a molecule, and is preferably represented by the following general formula (XVI).

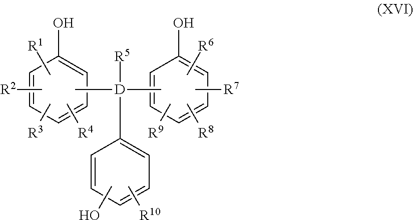

In the above formula (XVI), R¹ to R¹⁰ each represent independently a group selected from hydrogen, an alkyl group having 1 to 10 carbon atoms, a phenyl group, and a hydroxyl group. And, D represents a tetravalent organic group, and examples of such the tetravalent organic group are as follows:

### D:

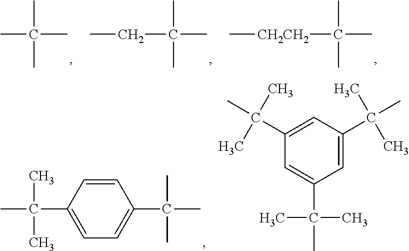

Specific examples of such the trisphenol-based compound include 4,4′,4″-methylidenetrisphenol, 4,4′-[1-[4-[1-(4-hydroxyphenyl)-1-methylethyl]phenyl]ethylidene]bisphenol, 4,4′,4″-ethylidynetris[2-methylphenol], 4,4′, 4″-ethylidynetrisphenol, 4,4′-[(2-hydroxyphenyl)methylene]bis[2-methylphenol], 4,4′-[(4-hydroxyphenyl)methylene]bis[2-methylphenol], 4,4′-[(2-hydroxyphenyl)methylene]bis(2,3-dimethylphenol), 4,4′-[(4-hydroxyphenyl)methylene]bis[2,6-dimethylphenol], 4,4′-[(3-hydroxyphenyl)methylene]bis[2,3-dimethylphenol], 2,2′-[(2-hydroxyphenyl)methylene]bis[3,5-dimethylphenol], 2,2′-[(4-hydroxyphenyl)methylene]bis[3,5-dimethylphenol], 2,2′-[(2-hydroxyphenyl)methylene]bis[2,3,5-trimethylphenol], 4,4′-[(2-hydroxyphenyl)methylene]bis[2,3,6-trimethylphenol], 4,4′-[(3-hydroxyphenyl)methylene]bis[2,3,6-trimethylphenol], 4,4′-[(4-hydroxyphenyl)methylene]bis[2,3,6-trimethylphenol], 4,4′-[(2-hydroxyphenyl)methylene]bis[2-cyclohexyl-5-methylphen ol], 4,4′-[(3-hydroxyphenyl)methylene]bis[2-cyclohexyl-5-methylphen ol], 4,4′-[(4-hydroxyphenyl)methylene]bis[2-cyclohexyl-5-methylphen ol], 4,4′-[(3,4-dihydroxyphenyl)methylene]bis[2-methylphenol], 4,4′-[(3,4-dihydroxyphenyl)methylene]bis[2,6-dimethylphenol], 4,4′-[(3,4-dihydroxyphenyl)methylene]bis[2,3,6-trimethylphenol], 4-[bis(3-cyclohexyl-4-hydroxy-6-methylphenyl)methyl]-1,2-benzenediol, 4,4′-[(2-hydroxyphenyl)methylene]bis[3-methylphenol], 4,4′,4″-(3-methyl-1-propanyl-3-ylidene)trisphenol, 4,4′-[(2-hydroxyphenyl)methylene]bis[2-methylethylphenol], 4,4′-[(3-hydroxyphenyl)methylene]bis[2-methylethylphenol], 4,4′-[(4-hydroxyphenyl)methylene]bis[2-methylethylphenol], 2,2′-[(3-hydroxyphenyl)methylene]bis[3,5,6-trimethylphenol], 2,2′-[(4-hydroxyphenyl)methylene]bis[3,5,6-trimethylphenol], 4,4′-[(2-hydroxyphenyl)methylene]bis[2-cyclohexylphenol], 4,4′-[(3-hydroxyphenyl)methylene]bis[2-cyclohexylphenol], 4,4′-[1-[4-[1-(4-hydroxy-3,5-dimethylphenyl)-1-methylethyl]phenyl]ethylidene]bis[2,6-dimethylphenol], 4,4′,4″-methylidynetris[2-cyclohexyl-5-methylphenol], 4,4′-[1-[4-[1-(3-cyclohexyl-4-hydroxyphenyl)-1-methylethyl]phenyl]ethylidene]bis[2-cyclohexylphenol], 2,2′-[(3,4-dihydroxyphenyl)methylene]bis[3,5-dimethylphenol], 4,4′-[(3,4-dihydroxyphenyl)methylene]bis[2-(methylethyl)phenol], 2,2′-[(3,4-dihydroxyphenyl)methylene]bis[3,5,6-trimethylphenol], 4,4′-[(3,4-dihydroxyphenyl)methylene]bis[2-cyclohexylphenol], α, α′, α″-tris(4-hydroxyphenyl)-1,3,5-triisopropylbenzene and the like.

When a phenol-based compound having 2 or more hydroxy groups in a molecule is used as the (C) epoxy resin curing agent, it is preferable that an equivalent ratio of an epoxy equivalent of the (B) epoxy resin and an OH equivalent of the phenol-based compound is in a range of 0.95 to 1.05:0.95 to 1.05. When the ratio is outside this range, an unreacted monomer remains, or a crosslinking density of a cured product is not sufficiently increased, being not preferable.

In addition, a curing promoter may be added to the adhesive film of the present invention. The curing promoter is not particularly limited, but imidazoles, dicyandiamide derivative, dicarboxylic acid dihydrazide, triphenylphosphine, tetraphenylphosphonium tetraphenylborate, 2-ethyl-4-methylimidazole tetraphenylborate, 1,8-diazabicyclo(5,4,0)undecene-7-tetraphenylborate and the like may be used. These may be used alone, or by combining two or more.

An amount of the curing promoter to be added is preferably 0.01 to 20 parts by weight, more preferably 0.1 to 10 parts by weight relative to 100 parts by weight of an epoxy resin. When the addition amount is smaller than 0.01 part by weight, there is a tendency that the curability is deteriorated. When the addition amount exceeds 20 parts by weight, there is a tendency that storage stability is deteriorated.

The adhesive film of the present invention may further contain a (D) filler. The (D) filler is not particularly limited, but examples thereof include metal fillers such as silver powders, gold powders, copper powders, nickel powders and the like, inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, ceramic and the like, and organic fillers such as carbon, rubber-based filler and the like. A shape of a filler is not particularly limited.

The filler can be variously used depending on the desired function. For example, the metal filler is added for the purpose of imparting electric conductivity, thermal conductivity, thixotropic property or the like to an adhesive composition, the non-metal inorganic filler is added for the purpose of imparting thermal conductivity, low thermal expanding property, low hygroscopicity or the like to an adhesive film, and the organic filler is added for the purpose of imparting toughness or the like to an adhesive film. These metal filler, inorganic filler and organic filler may be used alone, or by combining two or more. Inter alia, a metal filler, an inorganic filler and an insulating filler are preferable in that the desired properties can be imparted to a semiconductor device. Among the inorganic filler and the insulating filler, boron nitride is more preferable in that dispersity in a resin varnish is better, and a high adhering force at heating can be imparted.

It is preferable that an average particle diameter of the filler is 10 μm or smaller, and a maximum particle diameter is 25 μm or smaller. It is more preferable that an average particle diameter of the filler is 5 μm or smaller, and a maximum particle diameter is 20 μm or smaller. When an average particle diameter exceeds 10 μm, and a maximum particle diameter exceeds 25 μm, there is a tendency that effect of improvement in breakage toughness is not obtained. A lower limit is not particularly limited, but is usually around 0.1 μm in both diameters.

It is required that the filler satisfies both of an average particle diameter of 10 μm or smaller and a maximum particle diameter of 25 μm or smaller. When a filler having a maximum particle diameter of 25 μm or smaller but having an average particle diameter exceeding 10 μm is used, there is a tendency that a high adhesion strength is not obtained. In addition, when a filler having an average particle diameter of 10 μm or smaller but having a maximum particle diameter exceeding 25 μm is used, a particle diameter distribution is broadened, and an adhesion strength easily varies. In addition, when the adhesive composition of the present invention is used by processing into a thin film, there is a tendency that the surface becomes coarse and an adhesion force is reduced.

Examples of a method of measuring an average particle diameter and a maximum particle diameter of the filler include a method of measuring particle diameters of around 200 fillers using a scanning electron microscope (SEM).

Examples of a measuring method using SEM include a method of adhering a semiconductor chip and a semiconductor-supporting substrate using an adhesive composition, heating and curing this (preferably, at 150 to 200° C. for 1 to 10 hours) to prepare a sample, cutting a central part of this sample, and observing its section with SEM.

In addition, when a filler used is a metal filler or an inorganic filler, a method of heating an adhesive composition in an oven at 600° C. for two hours to degrade and volatilize a resin component, and observing and measuring the remaining filler with SEM can be adopted. When a filler itself is observed with SEM, a sample obtained by applying on a sample stage for SEM observation with a two-sided tape, scattering a filler on this adhesive surface and, thereafter, depositing thereon with ion sputtering is used. Thereupon, a probability of existence of the filler is made to be 80% or larger of a total filler.

An amount of the (D) filler to be used is determined depending on property or function to be imparted, and is 1 to 50% by volume, preferably 2 to 40% by volume, further preferably 5 to 30% by volume relative to a sum of a resin component containing (A) a thermoplastic resin, (B) an epoxy resin and (C) an epoxy resin curing agent and (D) a filler. When the amount is smaller than 1% by volume, there is a tendency that effect of imparting property or function due to addition of a filler is not obtained. When the amount exceeds 50% by volume, there is a tendency that adherability is reduced. By increasing an amount of a filler, an elastic modulus can be increased, and dicing property (cutting property with a dicer blade), wire bonding property (ultrasound efficacy), and an adhesion strength at heating can be effectively improved. However, when the amount is increased more than required, low application property and interface adherability with an object to be adhered which are characteristics of the present invention are deteriorated, and reliance including re-flowability resistance is reduced, being not preferable. In order to take balance between desired properties, an optimal content of a filler is determined.

In order to improve interface connection between different materials, various coupling agents may be added to the adhesive film of the present invention.

The adhesive film of the present invention can be obtained by mixing and kneading (A) a thermoplastic resin and (B) an epoxy resin and, if needed, (C) an epoxy resin curing agent, (D) a filler and other components in an organic solvent to prepare a vanish (vanish for coating adhesive film), forming a layer of the coating varnish on a substrate film, heating and drying this, and removing the substrate. The aforementioned mixing and kneading can be performed by appropriately combining the conventional stirrer, paddle machine, and dispersing machine such as triple roll and ball mill. The condition for the aforementioned heating and drying is not particularly limited as far as it is the condition under which a used solvent is sufficiently volatilized, but heating and drying is usually performed by heating at 60° C. to 200° C. for 0.1 to 90 minutes. In order to control a flow amount in the B stage state in a range of 100 to 1500 μm, it is desirable to reduce a remaining solvent as much as possible, and it is desirable to progress a reaction of curing an epoxy resin, or a bridging reaction between a polyimide resin and an epoxy resin to such an extent that application property is not deteriorated. From this point of view, it is preferable that a drying step at 120 to 160° C. for 10 to 60 minutes is included at film preparation.

An organic solvent used for preparing the varnish in preparation of the adhesive film, that is, a varnish solvent is not limited as far as it can uniformly dissolve, knead or disperse a material, but examples thereof include dimethylformamide, dimethylacetamide, N-methylpyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, ethyl acetate and the like. When a polyimide resin is used as a thermoplastic resin, a nitrogen-containing compound is preferable in that a reaction bridging a polyimide resin and an epoxy resin effectively progresses. Examples of such the solvent include the aforementioned dimethylformamide, dimethylacetamide, and N-methylpyrrolidone. Inter alia, N-methylpyrrolidone is preferable in that it is excellent in dissolving a polyimide resin.

A substrate film used in preparation of the adhesive film is not particularly limited as far as it stands the aforementioned heating and drying conditions, but examples thereof include a polyester film, a polypropylene film, a polyethylene terephthalate film, a polyimide film, a polyetherimide film, a polyethernaphthalate film, a methylpentene film and the like. These films as a substrate may be prepared into a multilayered film by combining two or more, or the surfaces of the films may be treated with a releasing agent of silicone series and silica series. Thereupon, a adhesive film with a substrate in which a substrate is not removed and is used as a support for a film, may be used.

Then, the present invention will be explained in more detail by referring to some preferable aspects.

A adhesive film as a first aspect of the present invention is characterized in that a tan δ peak temperature is −20 to 60° C., and a flow amount is 100 to 1500 μm. The tan δ peak temperature is a tan δ peak temperature around Tg, obtained by measuring a film which has been heated and cured under conditions of 180° C. and 5 hours, under conditions of a film size of 35 mm×10 mm, a temperature rising rate of 5° C./min, a frequency of 1 Hz and a measuring temperature of −100 to 300° C., using a viscoelasticity analyzer RSA-2 manufactured by Rheometrics. When a tan δ peak temperature of the film is lower than −20° C., self supportability as a film is lost and, when a tan δ peak temperature exceeds 60° C., there is an increased possibility that a laminating temperature exceeds 80° C., both cases being not preferable. In addition, the flow amount is a maximum value obtained by overlaying a euplux film of 10 mm×10 mm×50 μm thickness on the aforementioned film (uncured film) of 10 mm×10 mm×40 μm thickness size (Film thickness was adjusted at an error of ±5 μm. Hereinafter, the description of an error of a film thickness will be omitted because it is the same as that described above), holding a sample between these two slide glasses (manufactured by MATSUNAMI, 76 mm×26 mm×1.0 to 1.2 mm thickness), applying a load of 100 kgf/cm² on a hot platen at 180° C., thermally pressing this for 120 sec and, thereafter, observing a squeeze-out amount from the euplux film with a light microscope. When the flow amount thereupon is smaller than 100 μm, irregularities on a substrate with a wiring can not be sufficiently embedded by heat and pressure at transfer molding. On the other hand, when the flow amount exceeds 1500 μm, a film is flown due to thermal history at die bonding or wire bonding, air bubbles remaining in irregularities on the substrate are easily involved in those irregularities on the substrate and, even when heat and pressure are applied at a transfer molding step, the bubbles are not completely removed, and remain as voids in a film layer, and expansion easily occurs at hygroscopic re-flowing starting from the voids, both cases being not preferable. In addition, when a flow amount is measured regarding a adhesive film of 40 μm or thinner, a sample for measuring a flow amount may be prepared by applying an appropriate number of adhesive films to adjust a thickness. Conversely, when a adhesive film is thick, a sample for measuring a flow amount may be prepared by adjusting a thickness by means of careful cutting.

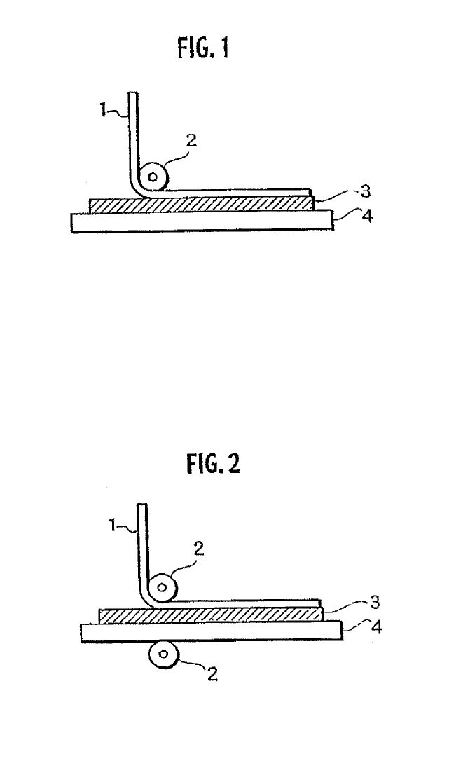

A adhesive film as one aspect of the present invention is characterized in that a 90° peeling force at 25° C. to a silicon wafer is 5N/m or larger at a stage of lamination on a back of a silicon wafer (back grind-treated side) at 80° C. Herein, the 90° peeling force will be explained using illustrations of FIG. 1 to FIG. 3.

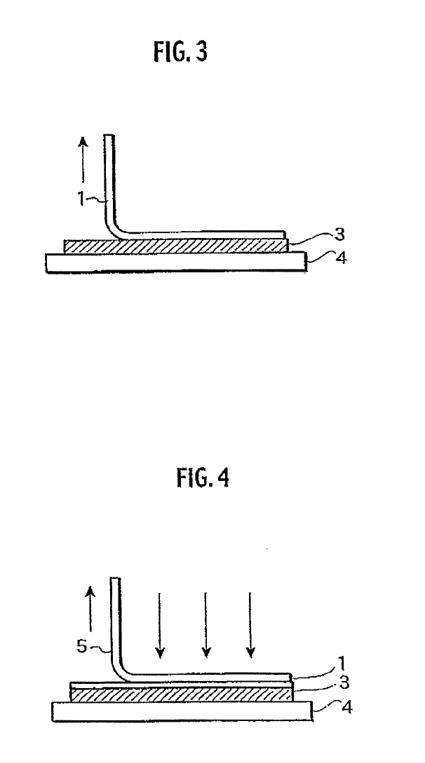

FIG. 1 and FIG. 2 show outline of a laminating method in which a adhesive film 1 of the present invention is laminated on a silicon wafer 3 using an apparatus having a roll 2 and a supporting stage 4. The 90° peeling force refers to a peeling force obtained by laminating a adhesive film having a thickness of 40 μm on a back of a silicone wafer having a size of 5 inch and a thickness of 400 μm under laminating conditions of a roll temperature of an apparatus: 40° C. and a supplying rate: 0.5 m/min and, thereafter, peeling a adhesive film (1 cm width) at a 90° direction under condition of 100 mm/min by the method shown in FIG. 3. The 90° peeling force is preferably 5N/m or larger. When the peeling force is smaller than 5N/m, there is an increased possibility that chip flight occurs at dicing, and it becomes difficult to maintain better picking up property. In order to assuredly maintain better picking up property without occurrence of chip flight, the peeling force is more preferably 20N/m or larger, particularly preferably 50N/m or larger.

It is preferable that, in the aforementioned laminating conditions, a laminating pressure is determined by a thickness and a size of a semiconductor wafer to be adhered. Specifically, when a thickness of a wafer is 10 to 600 μm, a linear pressure is preferably 0.5 to 20 kgf/cm. When a thickness of a wafer is 10 to 200 μm, a linear pressure of 0.5 to 5 kgf/cm is preferable. A size of a wafer is generally around 4 to 10 inch, being not limited to this. By adopting the aforementioned laminating conditions, balance between prevention of wafer cracking and maintenance of adherability at laminating can be retained.

A adhesive film as one aspect of the present invention is characterized in that, when a glass chip of 5 mm×5 mm×0.55 mm thickness is die-bonded on an organic substrate of a thickness of 0.1 mm with a solder resist layer of a thickness of 15 μm attached on the surface, with a adhesive film of 5 mm×5 mm×40 μm thickness under condition of Tg (herein, tan δ peak temperature) of a film+100° C.×500 gf/chip×3 sec, this is heated and pressed under condition of 180° C.×5 kgf/chip×90 sec, the adhesive film is heated and cured under condition of 180° C. and 5 hours, hygroscopically treated for 15 hours under condition of 85° C. and 85% relative humidity (hereinafter, also referred to as “RH”), and heated for 30 seconds on a hot platen at 260° C., occurrence of expansion is not recognized.

In addition to the aforementioned no recognition of occurrence of expansion, a adhesive film as one aspect of the present invention is characterized in that, when a silicon chip of 3.2 mm×3.2 mm×0.4 mm thickness is die-bonded on the aforementioned organic substrate with a adhesive film of 3.2 mm×3.2 mm×40 μm thickness under condition of Tg (herein, tan δ peak temperature) of a film+100° C.×500 gf/chip×3 sec, this is heated and pressed under condition of 180° C.×5 kgf/chip×90 sec, the adhesive film is heated and cured under condition of 180° C. and 5 hours, hygroscopically treated for 168 hours under condition of 85° C. and 60% RH, and heated for 30 seconds on a hot platen at 260° C., a shear adhesion strength is 5N/chip or larger and, further, when a silicon chip of 5 mm×5 mm×0.4 mm thickness is die-bonded on the aforementioned organic substrate with a adhesive film of 5 mm×5 mm×40 μm thickness under condition of Tg of a film+100° C.×500 gf/chip×3 sec, this is heated and pressed under condition of 180° C.×5 kgf/chip×90 sec, the adhesive film is heated and cured under condition of 180° C. and 5 hours, and heated for 30 seconds on a hot platen at 260° C., a peeling strength (peeling strength of silicon chip) is 5N/chip or larger.

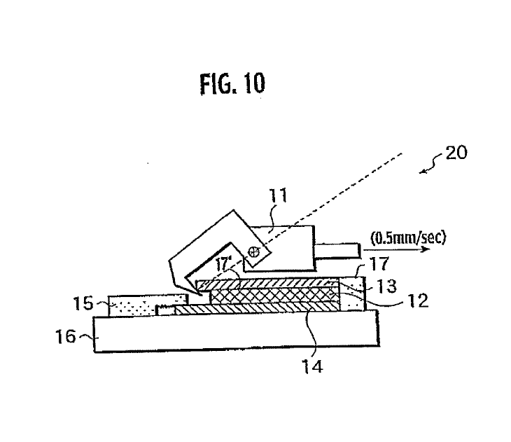

The presence or the absence of the aforementioned occurrence of expansion is determined by observation with naked eyes using a light microscope (×20 magnification). The aforementioned shear adhesion strength is measured under condition of a measuring rate: 500 μm/sec and a measuring gap: 500 μm using BT2400 manufactured by DAGE. The aforementioned peeling strength is measured under condition of a measuring rate: 0.5 mm/sec using an adhesion force tester shown in FIG. 10.

A adhesive film as one aspect of the present invention is characterized in that a difference between surface energy of the adhesive film before use, and surface energy of an organic substrate with a solder resist material is within 10 mN/m. When this difference exceeds 10 mN/m, it becomes difficult to maintain better wettability with the organic substrate, and a possibility of reduction in an interface adhesion force is increased, being not preferable. The surface energy is calculated from measured values of a contact angle for water and methylene iodide according to the following equations (1) to (3):

72.8(1+cos θ₁)=2[(21.8)^{1/2}·(γ^{d})^{1/2}+(51.0)^{1/2}·(γ^{p})^{1/2}] (1)

50.8(1+cos θ₂)=2[(48.5)^{1/2}·(γ^{d})^{1/2}+(2.3)^{1/2}·(γ^{p})^{1/2}] (2)

γ=γ^{d}+γ^{p} (3)

The θ₁ is a contact angle (deg) for water, θ₂ is a contact angle (deg) for methylene iodide, γ is surface energy, γ^{d} is a dispersion component of surface energy, and γ^{p} is a polar component of surface energy.

The contact angle was measured as follows: A adhesive film was excised into an appropriate size, this was applied and fixed to a slide glass with a double-adhesive tape, the surface of the adhesive film was washed with hexane, subjected to nitrogen-purging treatment, and dried under condition of 60° C. and 30 minutes to obtain a sample, which was used for measurement. A side for measuring a contact angle was on a substrate side at film coating. A contact angle was measured at room temperature using Model CA-D manufactured by Kyowahyomenkagaku.

A adhesive film as one aspect of the present invention is characterized in that it is used in a film-like die bonding material containing at least a thermoplastic resin and a thermosetting resin and, letting a remaining volatile matter of the adhesive film to be V (% by weight), water absorption after heating and curing to be M (% by weight), a flow amount to be F (μm) and a storage elastic modulus at 260° C. after heating and curing to be E (MPa), at least one condition of the following (1) to (4):

V≦10.65×E, (1)

M≦0.22×E, (2)

V≦−0.0043F+11.35, (3)

M≦−0.0002F+0.6 (4)

is satisfied.

In this case, it is preferable to simultaneously satisfy the above (3) and (4) conditions, it is more preferable to satisfy the above (2) to (4) conditions, and it is further preferable to satisfy all conditions of the above (1) to (4).

The remaining volatile matter V is obtained from: V=(weight of film before heating−weight of film after heating in oven under condition of 260° C. and 2 hours)/weight of film before heating, regarding a film after preparation. The water absorption M after heating and curing is obtained from: M=(weight of film after immersion in ion-exchanged water for 24 hours−weight of film before water absorption)/weight of film before water absorption, regarding a film which has been heated and cured under condition of 180° C. and 5 hours. A weight of a film before water absorption is a weight after dried in a vacuum drier under condition of 120° C. and 3 hours. The flow amount F is a value measured under the aforementioned condition. A storage elastic modulus E at 260° C. after heating and curing is a storage elastic modulus at 260° C. measured under conditions of a film size of 35 mm×10 mm, a temperature rising rate of 5° C./min, a frequency of 1 Hz and a measuring temperature of −50 to 300° C. using a viscoelasticity analyzer RSA-2 manufactured by Rheometrics, regarding a film which have been heated and cured under condition of 180° C. and 5 hours. When any of the aforementioned remaining volatile matter V, water absorption M, flow amount F and storage elastic modulus E (MPa) is outside the range of the aforementioned equations, it becomes difficult to simultaneously maintain low temperature laminating property and better re-flowability resistance in the present invention.

In addition, as one aspect of the present invention, an adhesive sheet in which a substrate layer, a self-adhesive layer, and the adhesive film layer of the present invention are formed in this order (i.e. an adhesive sheet in which the previous dicing tape and the adhesive film layer of the present invention are laminated) is provided. This adhesive sheet is an integrated-type adhesive sheet provided with at least a adhesive film and a dicing film for the purpose of simplifying a step of manufacturing a semiconductor device. That is, this is an adhesive sheet having properties required for both of a dicing film and a die bonding film.

Like this, by providing a self-adhesive layer exerting function as a dicing film on a substrate layer, and laminating the adhesive film layer exerting function as a die bonding film on the self-adhesive layer, function as a dicing film is exerted at dicing, and function as a die bonding film is exerted at die bonding. For this reason, the aforementioned integrated-type adhesive sheet can be used by picking up as a semiconductor chip with a adhesive film, after a adhesive film layer of an integrated-type adhesive sheet is laminated on a back of a semiconductor wafer while heating, and this is diced.

The self-adhesive layer may be either of pressure-sensitive type or radiation-curing type, but radiation-curing type is preferable in that it has a high adhering force at dicing and, by irradiating with ultraviolet-ray (UV) before picking up, it becomes to have a low adhering force, and an adhering force can be easily controlled. As the radiation-curing self-adhesive layer, the previously known radiation-curing self-adhesive layers may be used without any limitation, as far as they have such a sufficient adhering force that a semiconductor chip is not flied at dicing, and at a step of picking up a semiconductor chip, thereafter, they have such a low adhering force that a semiconductor chip is not damaged. Thereupon, at a stage of lamination on a silicon wafer at 80° C., letting a 90° peeling force at 25° C. of a adhesive film to the silicon wafer to be A, and a 90° peeling force at 25° C. of a radiation-curing type self-adhesive layer to a adhesive film after UV irradiation under condition of an exposed amount of 500 mJ/cm² to be B, a value of (A−B) is preferably 1N/m or larger, more preferably 5N/m or larger, more preferably 10N/m or larger. The 90° peeling force at 25° C. of a adhesive film to a silicon wafer is as described above. In addition, a 90° peeling force at 25° C. of a radiation-curing type self-adhesive layer to a adhesive film after UV irradiation under condition of an exposed amount of 500 mJ/cm² is a peeling force obtained by laminating on a back of a silicone wafer (back grind-treated surface) at 80° C. (laminating method is as described above), laminating the aforementioned dicing tape at room temperature, irradiating this with UV under condition of an exposed amount of 500 mJ/cm², and peeling the dicing tape from the adhesive film at a 90° direction at 25° C. More specifically, as shown in FIG. 4, a dicing tape 5 (1 cm width) is peeled at a 90° direction at 25° C. under condition of 100 mm/min (1: adhesive film, 3: silicon wafer, 4: support). When the value (A−B) is smaller than 1N/m, there is a tendency that each element is damaged at picking up, or peeling occurs in advance at an interface between a silicon chip and a adhesive film at picking up, and effective picking up can not be performed, being not preferable. The “peeling force” will be explained in more detail in the column of Examples later.

The 90° peeling force at 25° C. of a radiation-curing type self-adhesive layer to a adhesive film after UV irradiation under condition of an exposed amount of 500 mJ/cm²

As the radiation-curing type self-adhesive layer, the previously known radiation-curing type self-adhesive layers can be used without any limitation, as far as they have the aforementioned properties. As the radiation-curing type self-adhesive layer, specifically, a layer containing a self-adhesive and a radiation-polymerizable oligomer can be used. In this case, as a self-adhesive constituting the aforementioned radiation-curing type self-adhesive layer, an acrylic-based self-adhesive is preferable. More specifically, examples include (meth)acrylic acid ester copolymers containing (meth)acrylic acid ester or a derivative thereof as a main constituent monomer unit, or a mixture of these copolymers. Herein, the description of (meth) acrylic acid ester indicate both of methacrylic acid ester and acrylic acid ester.

Examples of the (meth)acrylic acid ester copolymer include copolymers of (a) at least one (meth) acrylic acid alkyl ester monomer selected from (meth)acrylic acid alkyl esters in which a number of carbon atoms in an alkyl group is 1 to 15, (b) at least one polar monomer having no acidic group selected from the group consisting of glycidyl(meth)acrylate, dimethylaminoethyl(meth)acrylate, diethylaminoethyl(meth)acrylate, 2-hydroxyethyl(meth)acrylate, vinyl acetate, styrene and vinyl chloride, and (c) at least one comonomer having an acidic group selected from the group consisting of acrylic acid, methacrylic acid and maleic acid.

A copolymerization ratio of (a) a (meth)acrylic acid alkyl ester monomer, (b) a polar monomer having no acidic group, and (c) a comonomer having an acidic group is preferably in a range of a/b/c=35 to 99/1 to 60/0 to 5 as expressed by a weight ratio. Alternatively, (c) the comonomer having an acidic group may not be used and, in this case, it is preferable that monomers are blended in a range of a/b=70 to 95/5 to 30.

When (b) the polar monomer having no acidic group as a comonomer is copolymerized above 60% by weight, a radiation-curing type self-adhesive layer 3 becomes a complete compatible system, an elastic modulus exceeds 10 MPa after radiation curing, and there is a tendency that sufficient expanding property and picking up property can not be obtained. On the other hand, when (b) the polar monomer having no acidic group is copolymerized below 1% by weight, a radiation-curing type self-adhesive layer 3 becomes an ununiform dispersion system, and there is a tendency that better adhesive properties can not be obtained.

When (meth) acrylic acid is used as a comonomer having an acidic group, it is preferable that an amount of (meth)acrylic acid to be copolymerized is 5% by weight or smaller. When (meth)acrylic acid as a comonomer having an acidic group is copolymerized above 5% by weight, a radiation-curing type self-adhesive layer 3 becomes a complete compatible system, and there is a tendency that sufficient expanding property and picking up property can not be obtained.

A weight average molecular weight of a (meth)acrylic acid ester copolymer which can be obtained by copolymerizing these monomers is preferably 2.0×10⁵ to 10.0×10⁵, more preferably 4.0×10⁵ to 8.0×10⁵.

A molecular weight of a radiation-polymerizable oligomer constituting a radiation-curing type self-adhesive layer is not particularly limited, but is usually around 3,000 to 30,000, preferably around 5,000 to 10,000.

It is preferable that the radiation-polymerizable oligomer is uniformly dispersed in a radiation-curing type self-adhesive layer. Its dispersion particle diameter is preferably 1 to 30 μm, more preferably 1 to 10 μm. A dispersion particle diameter is a value determined by observing a radiation-curing type self-adhesive layer 3 with a 600 magnification microscope, and actually measuring a particle diameter of a dispersed oligomer with a scale in the microscope. In addition, uniformly dispersed state (uniform dispersion) refers to the state where a distance between adjacent particles is 0.1 to 10 μm.

Examples of the radiation-polymerizable oligomer include compounds having at least one carbon-carbon double bond in a molecule, such as an urethane acrylate-based oligomer, an epoxy-modified urethane acrylate oligomer, an epoxy acrylate oligomer and the like. Inter alia, an urethane acrylate-based oligomer is preferable in that various compounds can be selected depending on the desired purpose.

The urethane acrylate-based oligomer can be obtained, for example, by reacting a polyol compound of polyester type or polyether type with a polyvalent isocyanate compound such as 2,4-tolylenediisocyanate, 2,6-tolylenediisocyanate, 1,3-xylylenediisocyanate, 1,4-xylylenediisocyanate, diphenylmethane, 4,4-diisocyanate and the like to obtain a terminal isocyanate urethane prepolymer, which is reacted with acrylate or methacrylate having a hydroxyl group, such as 2-hydroxyethyl acrylate, 2-hydroxyethyl methacrylate, 2-hydroxypropyl acrylate, 2-hydroxypropyl methacrylate, polyethylene glycol acrylate, polyethylene glycol methacrylate and the like.

A molecular weight of the urethane acrylate-based oligomer is not particularly limited, but is preferably 3,000 to 30,000, more preferably 3,000 to 10,000, extremely preferably 4,000 to 8,000.

In the adhesive sheet of the present invention, as a blending ratio of a self-adhesive agent and a radiation-polymerizable oligomer in a radiation-curing type self-adhesive layer, a radiation-polymerizable oligomer is used preferably at 20 to 200 parts by weight, more preferably 50 to 150 parts by weight relative to 100 parts by weight of a self-adhesive.

By adopting the aforementioned blending ratio, a great initial adhering force between a radiation-curing type self-adhesive layer and a die adhering adhesive layer is obtained and, moreover, after irradiation with radiation, an adhering force is greatly decreased, and a wafer chip and a die adhering adhesive layer can be easily picked up from the self-adhesive sheet. In addition, an elastic modulus is maintained to an extent, in an expanding step, a desired chip interval can be easily obtained, and deviation of a chip does not occur, and therefore, picking up can be stably performed. If needed, other components may be further added in addition to the aforementioned components.

The adhesive film of the present invention is a die bonding adhesive material for laminating a semiconductor chip such as IC, LSI and the like, with a semiconductor-carrying support member such as a lead frame such as a 42 alloy lead frame, a copper lead frame and the like, a substrate such as a plastic film such as a polyimide resin, an epoxy resin and the like, a glass non-woven fabric and the like, which is impregnated with a plastic such as a polyimide resin, an epoxy resin and the like, and is cured, and a ceramic such as alumina and the like. Inter alia, the adhesive film of the present invention is suitably used as a die bonding adhesive material for laminating with an organic substrate with an organic resist layer. Alternatively, the adhesive film of the present invention is also suitably used as an adhesive material for adhering a semiconductor chip and a semiconductor chip, in Stacked-PKG having a structure in which a plurality of semiconductor chips are stacked.

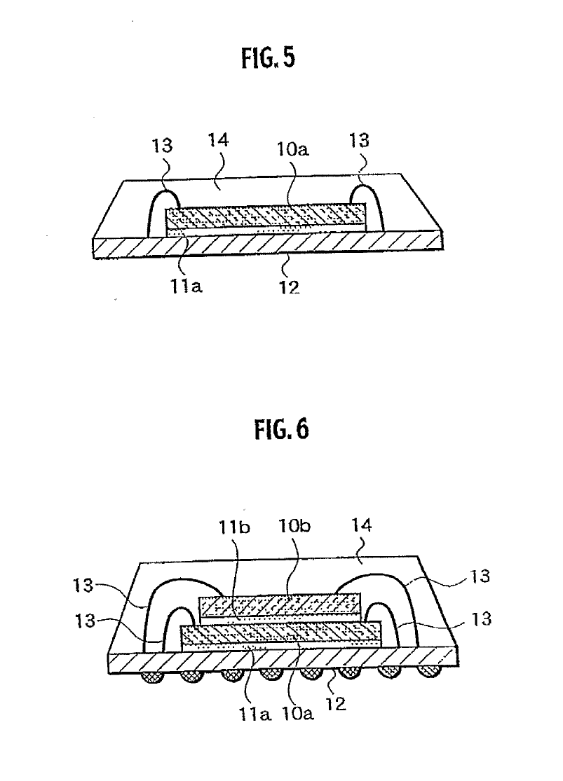

FIG. 5 shows a semiconductor device having a general structure.

In FIG. 5, a semiconductor chip 10a is adhered to a semiconductor chip supporting member 12 via the adhesive film 11a of the present invention, and a connecting terminal (not shown) of the semiconductor chip 10a is electrically connected to an external connecting terminal (not shown) via a wire 13, and is sealed with a sealing material 14. Recently, semiconductor devices having various structures have been proposed, and utility of the adhesive film of the present invention is not limited to this structure.

In addition, FIG. 6 shows one example of a semiconductor device having a structure in which semiconductor chips are adhered.

In FIG. 6, a first tier semiconductor chip 10a is adhered to a semiconductor chip support member 12 via the adhesive film 11a of the present invention, and a second tier semiconductor chip 10b is further adhered on the first tier semiconductor chip 10a via the adhesive film 11b of the present invention. Connecting terminals (not shown) of the first tier semiconductor chip 10a and the second tier semiconductor chip 10b are electrically connected to an external connecting terminal (not shown) via a wire 13, and sealed with a sealing material (not shown). Like this, the adhesive film of the present invention can be also suitably used in a semiconductor device having a structure in which a plurality of semiconductor chips are stacked.

In addition, a heating temperature when the adhesive film of the present invention is held between the aforementioned semiconductor chip and support member, and heated and pressed to adhere both of them, is usually 25 to 200° C. for 0.1 to 300 seconds. Thereafter, a semiconductor device (semiconductor package) is obtained via steps such as a wire bonding step and, if needed, a sealing step with a sealing material.

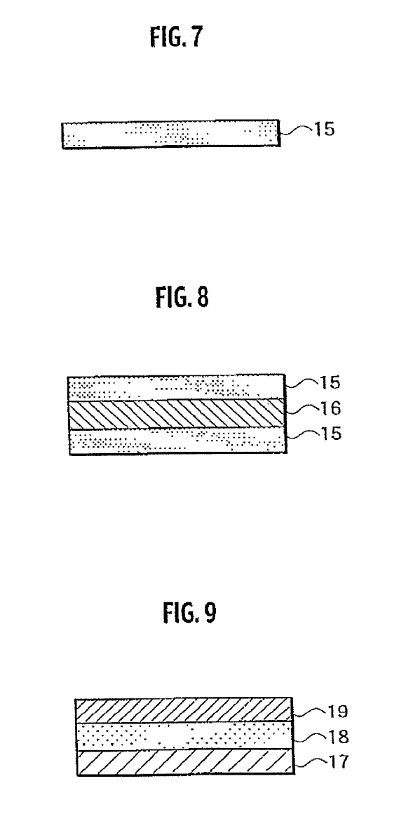

It is preferable that the adhesive film of the present invention is a monolayer adhesive film composed only of an adhesive layer 15 as shown in FIG. 7, but the adhesive film of the present invention may have a structure in which an adhesive layer 15 may be disposed on both sides of a substrate film 16 as shown in FIG. 8. Alternatively, in order to prevent damage and pollution of an adhesive layer, a cover film may be appropriately disposed on an adhesive layer. It is preferable that the adhesive film of the present invention has a shape such as a tape having a width of around 0.5 mm to 20 mm, a sheet having such a size that the adhesive is laminated every one semiconductor wafer, a continuous sheet and the like. In addition, in the case of a form such as a tape and a continuous sheet, when the adhesive is wound up on a winding core, it is easily stored, and is also convenient upon use. A winding up length is not particularly limited, but when the length is too small, exchange becomes troublesome, and when the length is too large, a high pressure is applied to a central part, and a thickness may be changed. Thus, the length is appropriately set in a range of usually 20 m to 1000 m.

In addition, as one aspect of the present invention, there is provided an adhesive sheet in which a substrate layer 17, a radiation-curing type self-adhesive layer 18, and the aforementioned adhesive film layer 19 are formed in this order (FIG. 9). The adhesive sheet is an integrated-type adhesive sheet in which a dicing film is laminated on the resulting adhesive film with a substrate, for the purpose of simplifying a step of manufacturing a semiconductor device. The integrated-type adhesive sheet is used by picking up as a semiconductor chip with a adhesive film, after a adhesive film layer of an integrated-type adhesive sheet is laminated on a back of a semiconductor wafer while heating, and this is diced.

The adhesive film of the present invention is excellent in low temperature laminating property and picking up property after dicing as a material for adhering an electronic part such as a semiconductor chip and the like, with a support member such as a lead frame and an insulating support substrate and, at the same time, has excellent reliance on better thermal adhering force and thermal history of high temperature soldering at packaging and, therefore, can be suitably used as a die bonding material of a semiconductor package corresponding to lead free. In addition, a semiconductor device containing a structure in which a semiconductor chip and a support member are adhered using the adhesive composition or the adhesive film of the present invention is excellent in reliance.

### EXAMPLE

The present invention will be illustrated in detail by way of Examples. The present invention is not limited to them.

### Examples 1 to 17

### Comparative Examples 1 to 10

Using the following polyimides A to M as thermoplastic resins, film coating varnishes were prepared according to the formulation table in the following Table 2.

### <Polyimide A>

2.10 g (0.035 mol) of 1,12-diaminododecane, 17.31 g (0.03 mol) of polyetherdiamine (ED2000 manufactured by BASF (molecular weight: 1923)), 2.61 g (0.035 mol) of 1,3-bis(3-aminopropyl)tetramethyldisiloxane (LP-7100 manufactured by Shin-Etsu Chemical Co., Ltd.) and 150 g of N-methyl-2-pyrrolidone were placed into a 300 ml flask equipped with a thermometer, a stirrer and a calcium chloride tube, followed by stirring. After diamine was dissolved, 15.62 g (0.10 mol) of 4,4′-(4,4′-isopropylidenediphenoxy)bis(phthalic dianhydride) (difference between heat generation initiating temperature and heat generation peak temperature by DSC: 2.5° C.) which had been purified by recrystallization with acetic anhydride, was added in potions while the flask was cooled in an ice bath. After reacted at room temperature for 8 hours, 100 g of xylene was added, the material was heated at 180° C. while a nitrogen gas was blown, and xylene was removed by azeotroping with water, to obtain a polyimide solution (polyimide A). (Tg of polyimide: 22° C., weight average molecular weight: 47000, SP value: 10.2)

### <Polyimide A′>

According to the same manner as that of <Polyimide A> except that unpurified 4,4′-(4,4′-isopropylidenediphenoxy)bis(phthalic dianhydride) (difference between heat generation initiating temperature and heat generation peak temperature by DSCV: 11.1° C. was used in place of purified 4,4′-(4,4′-isopropylidenediphenoxy)bis(phthalic dianhydride), a polyimide solution (Polyimide A′) was obtained. (Tg of polyimide: 22° C., weight average molecular weight: 42000, SP value: 10.2)

### <Polyimide B>

8.63 g (0.07 mole) of 2,2-bis(4-aminophenoxyphenyl)propane, 17.31 g (0.03 mole) of polyetherdiamine (ED2000 manufactured by BASF (molecular weight: 1923)) and 166.4 g of N-methyl-2-pyrrolidone were placed into a 300 ml flask equipped with a thermometer, a stirrer and a calcium chloride tube, followed by stirring. After diamine was dissolved, 7.82 g (0.05 mole) of 4,4′-(4,4′-isopropylidenediphenoxy)bis(phthalic dianhydride) (difference between heat generation initiating temperature and heat generation peak temperature by DSC: 2.5° C.) which had been purified by recrystallization with acetic anhydride and 7.85 g (0.05 mole) of decamethylenebistrimellitate dianhydride (difference between heat generation initiating temperature and heat generation peak temperature by DSC: 5.0° C.) which had been purified by recrystallization with acetic anhydride, were added in portions while the flask was cooled in an ice bath. After reacted at room temperature for 8 hours, 111 g of xylene was added, the material was heated at 180° C. while a nitrogen gas was blown, and xylene was removed by azeotroping with water, to obtain a polyimide solution (Polyimide B). (Tg of polyimide: 33° C., weight average molecular weight: 114800, SP value: 10.1)

### <Polyimide C>

5.81 g (0.095 mole) of 4,9-dioxadecane-1,12-diamine, 2.88 g (0.005 mole) of polyetherdiamine (ED2000 manufactured by BASF (molecular weight: 1923)) and 112.36 g of N-methyl-2-pyrrolidone were placed into a 300 ml flask equipped with a thermometer, a stirrer and a calcium chloride tube, followed by stirring. After diamine was dissolved, 10.94 g (0.07 mol) of 4,4′-(4,4′-isopropylidenediphenoxy)bis(phthalic dianhydride) (difference between heat generation initiating temperature and heat generation peak temperature by DSC: 2.5° C.) which had been purified by recrystallization with acetic anhydride, and 4.71 g (0.03 mole) of decamethylenebistrimellitate dianhydride (difference between heat generation initiating temperature and heat generation peak temperature by DSC: 5.0° C.) which had been purified by recrystallization with acetic anhydride, were added in portions while the flask was cooled in an ice bath. After reacted at room temperature for 8 hours, 74.91 g of xylene was added, the material was heated at 180° C. while a nitrogen gas was blown, and xylene was removed by azeotroping with water, to obtain a polyimide solution (Polyimide C). (Tg of polyimide: 35° C., weight average molecular weight: 172300, SP value: 11.0)

### <Polyimide D>

4.62 g (0.07 mole) of 4,7,10-trioxatridecane-1,13-diamine, 2.24 g (0.03 mole) of 1,3-bis(3-aminopropyl)tetramethyldisiloxane (LP-7100 manufactured by Shin-Etsu Chemical Co. Ltd.), and 90.00 g of N-methyl-2-pyrrolidone were placed into a 300 ml flask equipped with a thermometer, a stirrer and a calcium chloride tube, followed by stirring. After diamine was dissolved, 12.50 g (0.08 mole) of 4,4′-(4,4′-isopropylidenediphenoxy)bis(phthalic dianhydride) (difference between heat generation initiating temperature and heat generation peak temperature by DSC: 2.5° C.) which had been purified by recrystallization with acetic anhydride, and 3.14 g (0.02 mole) of decamethylenebistrimellitate dianhydride (difference between heat generation initiating temperature and heat generation peak temperature by DSC: 5.0° C.) which had been purified by recrystallization with acetic anhydride, were added in portions while the flask was cooled in an ice bath. After reacted at room temperature for 8 hours, 60.00 g of xylene was added, the material was heated at 180° C. while a nitrogen gas was blown, and xylene was removed by azeotroping with water, to obtain a polyimide solution (Polyimide D). (Tg of polyimide: 24° C., weight average molecular weight: 42800, SP value: 11.0)

### <Polyimide E>

5.81 g (0.095 mole) of 4,9-dioxadecane-1,12-diamine, 2.88 g (0.005 mole) of polyetherdiamine (ED2000 manufactured by BASF (molecular weight: 1923)) and 97.32 g of N-methyl-2-pyrrolidone were placed into a 300 ml flask equipped with a thermometer, a stirrer and a calcium chloride tube, followed by stirring. After diamine was dissolved, 12.50 g (0.08 mole) of 4,4′-(4,4′-isopropylidenediphenoxy)bis(phthalic dianhydride) (difference between heat generation initiating temperature and heat generation peak temperature by DSC: 2.5° C.) which had been purified by recrystallization with acetic anhydride, and 3.14 g (0.02 mole) of decamethylenebistrimillitate dianhydride (difference between heat generation initiating temperature and heat generation peak temperature by DSC: 5.0° C.) which had been purified by recrystallization with acetic anhydride, were added in portions while the flask was cooled in an ice bath. After reacted at room temperature for 8 hours, 64.88 g of xylene was added, the material was heated at 180° C. while a nitrogen gas was blown, and xylene was removed by azeotroping with water, to obtain a polyimide solution (Polyimide E). (Tg of polyimide: 37° C., weight average molecular weight: 48500, SP value: 10.9)

### <Polyimide F>

5.41 g (0.045 mole) of 1,12-diaminododecane, 11.54 g (0.01 mole) of polyetherdiamine (ED2000 manufactured by BASF (molecular weight: 1923)), 24.3 g (0.045 mole) of polysiloxanediamine (KF-8010 manufactured by Shin-Etsu Silicone Co., Ltd.) (molecular weight: 900)) and 169 g of N-methyl-2-pyrrolidone were placed into a 300 ml flask equipped with a thermometer, a stirrer and a calcium chloride tube, followed by stirring. After diamine was dissolved, 31.23 g (0.1 mole) of 4,4′-(4,4′-isopropylidenediphenoxy)bis(phthalic dianhydride) (difference between heat generation initiating temperature and heat generation peak temperature by DSC: 2.5° C.) which had been purified by recrystallization with acetic anhydride, was added in portions while the flask was cooled in an ice bath. After reacted at room temperature for 8 hours, 112.7 g of xylene was added, the material was heated at 180° C. while a nitrogen gas was blown, and xylene was removed by azeotroping with water, to obtain a polyimide solution (Polyimide F). (Tg of polyimide: 25° C., weight average molecular weight: 35000, SP value: 9.8)

### <Polyimide G>

6.83 g (0.05 mole) of 2,2-bis(4-aminophenoxyphenyl)propane, 3.40 g (0.05 mole) of 4,9-dioxadecane-1,12-diamine, and 110.5 g of N-methyl-2-pyrrolidone were placed into a 300 ml flask equipped with a thermometer, a stirrer and a calcium chloride tube, followed by stirring. After diamine was dissolved, 17.40 g (0.10 mole) of decamethylenebistrimellitate dianhydride (difference between heat generation initiating temperature and heat generation peak temperature by DSC: 5.0° C.) which had been purified by recrystallization with acetic anhydride, was added in portions while the flask was cooled in an ice bath. After reacted at room temperature for 8 hours, 74 g of xylene was added, the material was heated at 180° C. while a nitrogen gas was blown, and xylene was removed by azeotroping with water, to obtain a polyimide solution (Polyimide G). (Tg of polyimide: 73° C., weight average molecular weight: 84300, SP value: 10.9)

### <Polyimide H>

4.28 g (0.07 mole) of 4,9-dioxadecane-1,12-diamine, 1.87 g (0.025 mole) of 1,3-bis(3-aminopropyl)tetramethyldisiloxane (LP-7100 manufactured by Shin-Etsu Chemical Co., Ltd.), 1.32 g (0.005 mole) of polysiloxanediamine (KF-8010 manufactured by Shin-Etsu Silicone Co., Ltd.) (molecular weight: 900)) and 72.2 g of N-methyl-2-pyrrolidone were placed into a 300 ml flask equipped with a thermometer, a stirrer and a calcium chloride tube, followed by stirring. After diamine was dissolved, 7.44 g (0.08 mole) of 4,4′-oxydiphathalic dianhydride (difference between heat generation initiating temperature and heat generation peak temperature by DSC: 3.2° C.) which had been purified by recrystallization with acetic anhydride and 3.14 g (0.02 mole) of decamethylenebistrimellitate dianhydride (difference between heat generation initiating temperature and heat generation peak temperature by DSC: 5.0° C.) which had been purified by recrystallization with acetic anhydride, were added in portions while the flask was cooled in an ice bath. After reacted at room temperature for 8 hours, 48.13 g of xylene was added, the material was heated at 180° C. while a nitrogen gas was blown, and xylene was removed by azeotroping with water, to obtain a polyimide solution (Polyimide H). (Tg of polyimide: 40° C., weight average molecular weight: 91800, SP value: 12.3)

### <Polyimide I>

4.62 g (0.07 mole) of 4,7,10-trioxatridecane-1,13-diamine, 1.87 g (0.025 mole) of 1,3-bis(3-aminopropyl)tetramethyldisiloxane (LP7100 manufactured by Shin-Etsu Chemical Co., Ltd.), 1.32 g (0.005 mole) of polysiloxanediamine (KF-8010 manufactured by Shin-Etsu Silicone Co., Ltd. (molecular weight: 900)), and 73.56 g of N-methyl-2-pyrrolidone were placed into a 300 ml flask equipped with a thermometer, a stirrer and a calcium chloride tube, followed by stirring. After diamine was dissolved, 7.44 g (0.08 mole) of 4,4′-oxydiphthalic dianhydride (difference between heat generation initiating temperature and heat generation peak temperature by DSC: 3.2° C.) which had been purified by recrystallization with acetic anhydride, and 3.14 g (0.02 mole) of decamethylenebistrimellitate dianhydride (difference between heat generation initiating temperature and heat generation peak temperature by DSC: 5.0° C.) which had been purified by recrystallization with acetic anhydride, were added in portions while the flask was cooled in an ice bath. After reacted at room temperature for 8 hours, 49.04 g of xylene was added, the material was heated at 180° C. while a nitrogen gas was blown, and xylene was removed by azeotroping with water, to obtain a polyimide solution (Polyimide I). (Tg of polyimide: 37° C., weight average molecular weight: 35600, SP value: 12.4)

### <Polyimide J>

6.17 g (0.05 mole) of 2,2-bis(4-aminophenoxyphenyl)propane, 13.20 g (0.05 mole) of polysiloxanediamine (KF-8010 manufactured by Shin-Etsu Silicone Co., Ltd. (molecular weight: 900)), and 140.24 g of N-methyl-2-pyrrolidone were placed into a 300 ml flask equipped with a thermometer, a stirrer and a calcium chloride tube, followed by stirring. After diamine was dissolved, 15.69 g (0.10 mole) of decamethylenebistrimellitate dianhydride (difference between heat generation initiating temperature and heat generation peak temperature by DSC: 5.0° C.) which had been purified by recrystallization with acetic anhydride was added in portions while the flask was cooled in an ice bath. After reacted at room temperature for 8 hours, 93.49 g of xylene was added, the material was heated at 180° C. while a nitrogen gas was blown, and xylene was removed by azeotroping with water, to obtain a polyimide solution (Polyimide J). (Tg of polyimide: 30° C., weight average molecular weight: 45600, SP value: 9.9)

### <Polyimide K>

2.71 g (0.045 mole) of 1,12-diaminododecane, 5.77 g (0.01 mole) of polyetherdiamine (polyetherdiamine 2000 manufactured by BASF (molecular weight: 1923)), 3.35 g (0.045 mole) of 1,3-bis(3-aminopropyl)tetramethyldisiloxane (LP-7100 manufactured by Shin-Etsu Chemical Co., Ltd.) and 113 g of N-methyl-2-pyrrolidone were placed into a 300 ml flask equipped with a thermometer, a stirrer and a calcium chloride tube, followed by stirring. After diamine was dissolved, 15.62 g (0.1 mole) of 4,4′-(4,4′-isopropylidenediphenoxy)bis(phthalic dianhydride) (difference between heat generation initiating temperature and heat generation peak temperature by DSC: 2.5° C.) which had been purified by recrystallization using acetic anhydride was added in portions while the flask was cooled in an ice bath. After reacted at room temperature for 8 hours, 75.5 g of xylene was added, the material was heated at 180° C. while a nitrogen gas was blown, and xylene was removed by azeotroping with water, to obtain a polyimide solution (Polyimide K). (Tg of polyimide: 53° C., weight average molecular weight: 58000, SP value: 10.3)

### <Polyimide L>

13.67 g (0.10 mole) of 2,2-bis(4-aminophenoxyphenyl)propane, and 124 g of N-methyl-2-pyrrolidone were placed into a 300 ml flask equipped with a thermometer, a stirrer and a calcium chloride tube, followed by stirring. After diamine was dissolved, 17.40 g (0.10 mole) of decamethylenebistrimellitate dianhydride (difference between heat generation initiating temperature and heat generation peak temperature by DSC: 5.0° C.) which had been purified by recrystallization using acetic anhydride, was added in portions while the flask was cooled in an ice bath. After reacted at room temperature for 8 hours, 83 g of xylene was added, the material was heated at 180° C. while a nitrogen gas was blown, and xylene was removed by azeotroping with water, to obtain a polyimide solution (Polyimide L). (Tg of polyimide: 120° C., weight average molecular weight: 121000, SP value: 10.8)

### <Polyimide M>

2.73 g (0.02 mole) of 2,2-bis(4-aminophenoxyphenyl)propane, 24.00 g (0.08 mole) of polysiloxanediamine (KF-8010 manufactured by Shin-Etsu Silicone Co., Ltd., molecular weight: 900), and 176.5 g of N-methyl-2-pyrrolidone were placed into a 300 ml flask equipped with a thermometer, a stirrer and a calcium chloride tube, followed by stirring. After diamine was dissolved, 17.40 g (0.10 mole) of decamethylenebistrimellitate dianhydride (difference between heat generation initiating temperature and heat generation peak temperature by DSC: 5.0° C.) which had been purified by recrystallization using acetic anhydride, was added in portions while the flask was cooled in an ice bath. After reacted at room temperature for 8 hours, 117.7 g of xylene was added, the material was heated at 180° C. while a nitrogen gas was blown, and xylene was removed by azeotroping with water, to obtain a polyimide solution (Polyimide M). (Tg of polyimide: 40° C., weight average molecular weight: 19700, SP value: 9.7)

TABLE 2
Formulation table of varnish

| | Polyimide | | | Epoxy resin | Curing | | |
|---|---|---|---|---|---|---|---|
| | resin | Epoxy resin 1 | Epoxy resin 2 | curing | promoter | | Solvent |
| | (part by | (part by | (part by | agent (part | (part by | Filler | (part by |
| | weight) | weight) | weight) | by weight) | weight) | (Vol %) | weight) |
| Example 1 | A | ESCN195 | — | — | — | HP-P1 | NMP |
| | (100) | (11.7) | | | | (15) | (420) |
| Example 2 | A | ESCN195 | — | TrisP-PA | TPPK | HP-P1 | NMP |
| | (100) | (11.7) | | (8.2) | (0.1) | (15) | (420) |
| Example 3 | B | ESCN195 | — | TrisP-PA | TPPK | HP-P1 | NMP |
| | (100) | (11.7) | | (8.2) | (0.1) | (15) | (420) |
| Example 4 | C | ESCN195 | — | TrisP-PA | TPPK | HP-P1 | NMP |
| | (100) | (11.7) | | (8.2) | (0.1) | (15) | (420) |
| Example 5 | D | ESCN195 | — | TrisP-PA | TPPK | HP-P1 | NMP |
| | (100) | (11.7) | | (8.2) | (0.1) | (15) | (420) |
| Example 6 | E | ESCN195 | — | TrisP-PA | TPPK | HP-P1 | NMP |
| | (100) | (11.7) | | (8.2) | (0.1) | (15) | (420) |
| Example 7 | K | ESCN195 | BEO-60E | NH-7000 | TPPK | HP-P1 | NMP |
| | (100) | (11.7) | (14.4) | (13.7) | (0.3) | (15) | (420) |
| Example 8 | K | ESCN195 | XB-4122 | TrisP-PA | TPPK | SE-1 | NMP |
| | (100) | (11.7) | (21.0) | (13.0) | (0.3) | (15) | (420) |
| Example 9 | K | ESCN195 | BEO-60E | — | TPPK | HP-P1 | NMP |
| | (100) | (11.7) | (14.4) | | (0.3) | (15) | (420) |
| Example 10 | K | N-730 | — | NH-7000 | TPPK | HP-P1 | NMP |
| | (100) | (11.0) | | (13.7) | (0.11) | (15) | (420) |
| Example 11 | K | N-730 | BEO-60E | NH-7000 | TPPK | HP-P1 | NMP |
| | (100) | (11.0) | (14.4) | (13.7) | (0.25) | (15) | (420) |
| Example 12 | K | ESCN195 | N-730 | NH-7000 | TPPK | HP-P1 | NMP |
| | (100) | (11.7) | (11.0) | (13.7) | (0.23) | (15) | (420) |
| Example 13 | K | ESCN195 | — | NH-7000 | TPPK | HP-P1 | NMP |
| | (100) | (11.7) | | (8.2) | (0.12) | (15) | (420) |
| Example 14 | K | EXA830CRP | — | NH-7000 | TPPK | HP-P1 | NMP |
| | (100) | (12.0) | | (10.5) | (0.12) | (15) | (420) |
| Example 15 | K | N-730 | — | NH-7000 | TPPK | HP-P1 | NMP |
| | (100) | (5.5) | | (4.4) | (0.05) | (15) | (420) |
| Example 16 | K | ESLV-80DE | — | NH-7000 | | HP-P1 | NMP |
| | (100) | (11.0) | | (8.8) | | (15) | (420) |
| Example 17 | K | ESLV-80DE | EXA830CRP | NH-7000 | | HP-P1 | NMP |
| | (100) | (11.0) | (12.0) | (19.3) | | (15) | (420) |
| Comparative | A′ | ESCN195 | — | TrisP-PA | TPPK | HP-P1 | NMP |
| Example 1 | (100) | (11.7) | | (8.2) | (0.1) | (15) | (420) |
| Comparative | F | N-730 | — | H-1 | 2PZ-CN | HP-P1 | NMP |
| Example 2 | (100) | (6.5) | | (3.9) | (0.2) | (5) | (420) |
| Comparative | G | BPO-20E | — | XL-225 | TPPK | HP-P1 | NMP |
| Example 3 | (100) | (14.4) | | (8.0) | (0.2) | (10) | (420) |
| Comparative | H | ESCN195 | — | TrisP-PA | TPPK | HP-P1 | NMP |
| Example 4 | (100) | (11.7) | | (8.2) | (0.1) | (15) | (420) |
| Comparative | I | ESCN195 | — | TrisP-PA | TPPK | HP-P1 | NMP |
| Example 5 | (100) | (11.7) | | (8.2) | (0.1) | (15) | (420) |
| Comparative | J | ESCN195 | — | TrisP-PA | TPPK | HP-P1 | NMP |
| Example 6 | (100) | (11.7) | | (8.2) | (0.1) | (15) | (420) |
| Comparative | L | EXA830CRP | — | H-1 | TPPK | — | NMP |
| Example 7 | (100) | (24.0) | | (15.8) | (0.2) | | (560) |
| Comparative | G | ESCN195 | BEO-60E | XL-225 | 2PZ-CN | SE-1 | NMP |
| Example 8 | (100) | (16.6) | (5.2) | (17.2) | (1.0) | (20) | (560) |
| Comparative | M | EXA830CRP | — | H-1 | 2PZ-CN | E-03 | NMP |
| Example 9 | (100) | (12.0) | | (7.9) | (0.2) | (10) | (280) |
| Comparative | F | N-730 | — | TrisP-PA | TPPK | HP-P1 | NMP |
| Example 10 | (100) | (5.5) | | (4.5) | (0.1) | (5) | (257) |

Abbreviation
Epoxy resin
ESCN-195: Sumitomo Chemical Co., Ltd., cresol novolak-type solid epoxy resin (epoxy equivalent 200, molecular weight: 778), BEO-60E: Shinnihonrikagaku, ethylene oxide 6 mol-added bisphenol A-type liquid epoxy resin (epoxy equivalent: 373, molecular weight: 746), BPO20-E: Shinnihonrikagaku, propylene oxide 6 mol-added bisphenol A-type liquid epoxy resin (epoxy equivalent: 314, molecular weight: 628), XB-4122: Asahi Chiba alkylene oxide-added bisphenol A-type liquid epoxy resin (epoxy equivalent: 336, molecular weight: 672), N-730: Dainippon Ink and Chemicals, Incorporated, phenol novolak-type liquid epoxy resin (epoxy equivalent: 175, molecular weight: 600~800), EXA830CRP: Dainipponkagaku, bisphenol F-type liquid epoxy resin (epoxy equivalent: 160, molecular weight: 320), ESLV-80DE: Shinnihonrikagaku, phenylether-type solid epoxy resin (epoxy equivalent: 174, molecular weight: 348)
Other components
H-1: Meiwakasei, phenol novolak (OH equivalent: 106, molecular weight: 653), NH-7000: Nippon Kayaku Co., Ltd., naphthol novolak (OH equivalent: 140, molecular weight: 420), XL-225, Mitsuitouatsukagaku, xylylene-modified phenol novolak (OH equivalent: 175, molecular weight: 420), NH-7000: Nippon Kayaku Co., Ltd., naphthol novolak (OH equivalent: 175, molecular weight: 420), TrisP-PA: Honshu Chemical Industry Co., Ltd., Trisphenol novolak (OH equivalent: 141, molecular weight: 424), TPPK: Tokyo Kasei Kogyo Co., Ltd., Tetraphenylphosphonium tetraphenylborate, 2PZ-CN: Shikoku Kasei Kogyo, 1-cyanoethyl-2-phenylimidazole, NMP: Kanto Kagaku, N-methyl-2-pyrrolidone, HP-P1: Mizushima Goukintestu, boron nitride (average particle diameter: 1.0 μm, maximum particle diameter: 5.1 μm), E-03: Tokai Mineral, silica (average particle diameter: 4.0 μm, maximum particle diameter: 11.4 μm), SE-1: Tokuyama, silica (average particle diameter: 0.8 μm, maximum particle diameter: 3.1 μm)

These varnishes were coated on a substrate (releasing agent-treated PET) at a thickness of 40 μm, respectively, and heated at 80° C. for 30 minutes and at 150° C. for 30 minutes in an oven, followed by being peeled from a substrate at room temperature, to obtain a adhesive film.

Results of assessment of properties of adhesive films in Examples 1 to 17 and Comparative Examples 1 to 10 are shown in Table 3. Methods of measuring respective properties are as follows:

### <Surface Energy>

A adhesive film or an organic substrate with a resist material was applied and fixed to a slide glass with a double-adhesive tape, the surface of the adhesive film or the organic substrate with a resist material was washed with hexane, this was subjected to nitrogen-purging treatment, and dried under condition of 60° C. and 30 minutes to obtain a sample. Using this sample, contact angles for water and methylene iodide were measured at room temperature using Model CA-D manufactured by Kyowahyoumenkagaku. Regarding the adhesive film, a substrate side at film coating was used as a measuring side.

Using measured values of a contact angle, surface energy of the adhesive film or the organic substrate with a resist material was calculated according to the following equation:

72.8(1+cos θ₁)=2[(21.8)^{1/2}·(γ^{d})^{1/2}·(51.0)^{1/2}·(γ^{p})^{1/2}] (1)

50.8(1+cos θ₂)=2[(48.5)^{1/2}·(γ^{d})^{1/2}·(2.3)^{1/2}·(γ^{p})^{1/2}] (2)

γ=γ^{d}+γ^{p} (3)

The θ₁ is a contact angle (deg) for water, θ₂ is a contact angle (deg) for methylene iodide, γ is surface energy, γ^{d} is a dispersion component of surface energy, and γ^{p} is a polar component of surface energy. Surface energy of the organic substrate with a resist material was 41 mN/m.

### <Flow Amount>

A adhesive film (uncured film) of 10 mm×10 mm×40 μm thickness size was used as a sample, a euplex film of 10 mm×10 mm×50 μm thickness size was overlaid on the sample, this was held between two slide glasses (manufactured by MATSUNAMI, 76 mm×26 mm×1.0 to 1.2 mm thickness), a load of 100 kgf/cm² was applied on a hot platen at 180° C., this was heated and pressed for 120 sec, and a squeeze-out amount from the euplex film was observed with a graduated light microscope. A maximum value of the squeeze-out amount was adopted as a flow amount.

### <Water Absorption>

A adhesive film (film which has been heated and cured under condition of 180° C. and 5 hours) of 20 mm×20 mm×40 μm thickness size was used as a sample, the sample was dried in a vacuum drier at 120° C. for 3 hours, allowed to cool in a desiccator, a dry weight was measured (M1). The sample after drying was immersed in ion-exchanged water at room temperature for 24 hours, taken out, the surface of the sample was wiped with a filter, a weight was rapidly measured to obtain M2. Water absorption was calculated by: water absorption (wt %=[(M2−M1)/M1]×100.

### <260° C. Storage Elastic Modulus and tan δ Peak Temperature>

Regarding a adhesive film which has been heated and cured under condition of 180° C. and 5 hours, a storage elastic modulus at 260° C., and a tan δ peak temperature around Tg were estimated by measurement under conditions of a film size of 35 mm×10 mm×40 μm thickness, a temperature rising rate of 5° C./min, a frequency of 1 Hz and a measuring temperature of −100 to 300° C. using a viscoelasticity analyzer RSA-2 manufactured by Rheometrics.

### <Peeling Force>

Peeling force to wafer (vs. wafer): a adhesive film (uncured film) 1 after preparation which has a thickness of 40 μm was laminated on a back of a silicon wafer 3 using an apparatus having a roll 2 and a supporting stage 4 as shown in FIG. 2. Thereupon, the adhesive film 1 was laminated on a back of a 5-inch silicon wafer 3 having a thickness of 300 μm, under conditions of a roll temperature of an apparatus: 80° C., linear pressure: 4 kgf/cm, a supplying rate: 0.5 m/min. Thereafter, a peeling force when the adhesive film (1 cm width) was peeled at a 90° direction by the method shown in FIG. 3 was adopted as a peeling force to a wafer (measuring rate: 100 mm/min).

Peeling force of adhesive film to radiation-curing type self-adhesive layer (vs. dicing tape): A UV-type dicing tape 5 as a radiation-curing type self-adhesive layer was further laminated on another surface of a surface opposing to a wafer of the adhesive film 1 with a wafer. Laminating conditions were the same as laminating conditions for the adhesive film except that a roll temperature of an apparatus was room temperature (25° C.). Thereafter, the dicing tape was irradiated with radiation from a direction shown by an arrow in FIG. 4 under conditions of a wavelength of 300 to 450 nm (powder of lump: 3 kW, illuminance: 15 mW/cm²), and a light exposing amount of 500 mJ/cm² using a UV-330 HQP-2 type light exposing machine manufactured by Oak Seisakusho. Then, a peeling force when the dicing tape (1 cm width) was peeled at a 90° direction by the method shown in FIG. 4 was adopted as a peeling force of a adhesive film to a radiation-curing type self-adhesive layer (dicing tape) (measuring rate: 100 mm/min.).

### <Chip Flight at Dicing and Picking Up Property>

Under the aforementioned conditions, a adhesive film was laminated on a back of a 5-inch silicon wafer having a thickness of 400 μm (laminating temperature: 80° C.), the aforementioned dicing tape was laminated under the aforementioned condition and, thereafter, this was diced into a 5 mm×5 mm size under conditions of a dicing rate of 10 mm/sec and a rotation number of 30,000 rpm using a dicer, the presence or the absence of chip flight at that time was measured and, when the chip flight was 10% or smaller, this was regarded as no chip flight. Flight of a remaining part of a wafer end at chip excising was excluded from assessment.

Then, a dicing tape side of a sample having no chip flight was exposed under the aforementioned conditions, and peelability between the dicing tape and the adhesive film when individual chips were picked up with a tweezers, was assessed. Assessment criteria are as follows:

◯: Chips which can be picked up is 90% or larger.
Δ: Chips which can be picked up is not smaller than 50% and smaller than 90%.
X: Chips which can be picked up is smaller than 50%.

### <Expansion Resistance>

A glass chip of 5 mm×5 mm×0.55 mm thickness was die-bonded on an organic substrate of a thickness of 0.1 mm with a solder resist layer having a thickness of 15 μm on the surface with a adhesive film of 5 mm×5 mm×40 μm thickness under conditions of Tg (herein, tan δ peak temperature)+100° C.×500 gf/chip×3 sec, heated and pressed under conditions of 180° C.×5 kgf/chip×90 sec, the adhesive film was heated and cured under condition of 180° C. and 5 hours, hygroscopically treated for 15 hours under condition of 85° C. and 85% RH, and heated for 30 seconds on a hot platen at 260° C. to obtain a sample. The sample was assessed using a light microscope (×20 magnification). Assessment criteria are as follows:

◯: Expansion is smaller than 10% of a whole film.
Δ: Expansion is not smaller than 10% and smaller 50% of a whole film.
X: Expansion is 50% or larger of a whole film.

### <Shear Adhesion Strength>

A silicon chip of 3.2 mm×3.2 mm×0.4 mm thickness was die-bonded on the aforementioned organic layer with a adhesive film of 3.2 mm×3.2 mm×40 μm thickness under conditions of Tg+100° C.×500 gf/chip×3 sec, heated and pressed under conditions of 180° C.×5 kgf/chip×90 sec, the adhesive film was heated and cured under condition of 180° C. and 5 hours, hygroscopically treated for 168 hours under condition of 85° C. and 60% RH, and heated for 30 seconds on a hot platen at 260° C. Thereafter, a shear adhesion strength was measured under conditions of a measuring rate: 500 μm/sec and a measuring gap: 50 μm using BT2400 manufactured by Dage.

### <Peeling Strength>

A silicon chip of 5 mm×5 mm×0.4 μm thickness was die-bonded on the aforementioned organic substrate with a adhesive film of 5 mm×5 mm×40 μm thickness under conditions of Tg+100° C.×50 gf/chip×3 sec, heated and pressed under conditions of 180° C.×5 kgf/chip×90 sec, the adhesive film was heated and cured under condition of 180° C. and 5 hours, and heated for 30 seconds on a hot platen at 260° C. Thereafter, a peeling strength was measured under condition of a measuring rate: 0.5 mm/sec using an adhering force assessing apparatus shown in FIG. 10.

### <Re-Flowability Resistance>

A silicon chip of 6.5 mm×6.5 mm×280 μm thickness was die-bonded with a adhesive film of 6.5 mm×6.5 mm×40 μm thickness on an organic substrate having a thickness of 0.1 mm with a copper wiring (wiring height 12 μm), which is equipped with a solder resist layer having a thickness of 15 μm on the surface under conditions of Tg of a film (herein, tan δ peak temperature)+100° C.×500 gf/chip×3 sec, thermal history corresponding to wire bonding was applied under condition of 170° C. and 3 minutes and, thereafter, transfer molding was performed (mold temperature: 180° C., curing time: 2 min) to heat and cure a sealing material in an oven under condition of 180° C. and 5 hours, to obtain a semiconductor package (CSP 96 pin, sealing region: 10 mm×10 mm, thickness: 0.8 mm). This package was water absorption-treated in a constant temperature and constant humidity tank under conditions of 30° C., 60% RH and 192 hours, and placed into an IR re-flow apparatus manufactured by TAMURA (package surface peak temperature: 265° C., temperature profile: adjusted according to JEDEC specification, based on a package surface temperature) repeatedly three times. And, the presence or the absence of peeling and breakage of a die-bonding layer was investigated using an ultrasound probing imaging apparatus HYE-FOUCUS manufactured by Hitachi, Ltd. Thereafter, a central part of the package was cut, a cut surface was polished, a cross-section of the package was observed using a metal microscope manufactured by Olympus, and the presence or the absence of peeling and breakage of a die-bonding layer was investigated. No recognition of these peeling and breakage was used as assessment criteria of re-flowability resistance.

### <Humidity Resistance Reliance>

Humidity resistance assessment was performed by observing peeling by the aforementioned method, after the aforementioned package was treated for 72 hours under conditions of a temperature of 121° C., a humidity of 100%, and 2.03×10⁵ Pa atmosphere (pressure cooker test: PCT treatment). Assessment criteria are as follows:

◯: Peeling occurrence rate: smaller than 10%
Δ: Peeling occurrence rate: not smaller than 10% and smaller than 50%
X: Peeling occurrence rate: 50% or larger

TABLE 3
Properties of film-like adhesive

| | | | | 260° C. | | | |
|---|---|---|---|---|---|---|---|
| | | | | storage | Tan δ | Peeling force | |
| | Surface | Flow | Water | elastic | peak | (N/m) | |
| | energy* | amount | absorption | modulus | temperature | vs. | vs. dicing |
| | (mN/m) | (μm) | (% by weight) | (MPa) | (° C.) | wafer | tape |
| Example 1 | 38(3) | 435 | 0.33 | 2.0 | 30.7 | 141 | 10 |
| Example 2 | 39(2) | 542 | 0.33 | 3.2 | 21.7 | 172 | 15 |
| Example 3 | 37(4) | 400 | 0.39 | 6.0 | 23.0 | 126 | 20 |
| Example 4 | 42(1) | 915 | 0.44 | 7.0 | 48.0 | 95 | 21 |
| Example 5 | 42(1) | 1270 | 0.43 | 1.9 | 23.4 | 180 | 19 |
| Example 6 | 40(1) | 1310 | 0.42 | 1.3 | 49.2 | 92 | 18 |
| Example 7 | 40(1) | 635 | 0.33 | 7.0 | 54.0 | 20 | 5 |
| Example 8 | 37(4) | 795 | 0.48 | 2.1 | 54.0 | 50 | 4 |
| Example 9 | 37(4) | 665 | 0.47 | 1.0 | 40.0 | 35 | 5 |
| Example 10 | 38(3) | 810 | 0.29 | 6.8 | 56.0 | 37 | 15 |
| Example 11 | 37(4) | 920 | 0.34 | 6.3 | 51.0 | 42 | 20 |
| Example 12 | 38(3) | 760 | 0.31 | 5.2 | 56.3 | 20 | 5 |
| Example 13 | 38(3) | 530 | 0.33 | 7.4 | 58.2 | 8 | 5 |
| Example 14 | 38(3) | 730 | 0.31 | 3.6 | 56.0 | 19 | 15 |
| Example 15 | 38(3) | 760 | 0.34 | 2.1 | 56.0 | 21 | 16 |
| Example 16 | 38(3) | 620 | 0.26 | 6.3 | 58.0 | 9 | 5 |
| Example 17 | 37(4) | 660 | 0.29 | 6.4 | 56.2 | 19 | 13 |
| Comparative | 38(3) | 2810 | 0.33 | 0.5 | 21.0 | 183 | 12 |
| Example 1 | | | | | | | |
| Comparative | 27(14) | 2103 | 0.05 | 3.6 | 34.0 | 40 | 30 |
| Example 2 | | | | | | | |
| Comparative | 41(0) | 430 | 0.42 | 3.3 | 79.0 | 2 | — |
| Example 3 | | | | | | | |
| Comparative | 48(7) | 92 | 0.48 | 4.5 | 52.0 | 63 | 26 |
| Example 4 | | | | | | | |
| Comparative | 52(11) | 96 | 0.53 | 4.3 | 51.2 | 65 | 30 |
| Example 5 | | | | | | | |
| Comparative | 26(15) | 2340 | 0.01 | 0.5 | 49.3 | 105 | 21 |
| Example 6 | | | | | | | |
| Comparative | 46(5) | 25 | 0.22 | 5.2 | 120.0 | 0 | 5 |
| Example 7 | | | | | | | |
| Comparative | 41(0) | 430 | 0.31 | 2.3 | 79.0 | 0 | 4 |
| Example 8 | | | | | | | |
| Comparative | 26(15) | 2170 | 0.05 | melt flow | 56.0 | 15 | 30 |
| Example 9 | | | | | | | |
| Comparative | 27(14) | 2100 | 0.01 | melt flow | 34.0 | 22 | 33 |
| Example 10 | | | | | | | |

| | Presence | | | Shear | | | |
|---|---|---|---|---|---|---|---|
| | or absence | Picking | | adhesion | Peeling | Re- | |
| | of chip | up | Expansion | strength | strength | flowability | Humidity |
| | flight | property | resistance | (N/inch) | (N/inch) | resistance | reliance |
| Example 1 | Absence | ◯ | ◯ | 15.0 | 40.0 | ◯ | ◯ |
| Example 2 | Absence | ◯ | ◯ | 14.1 | 39.0 | ◯ | ◯ |
| Example 3 | Absence | ◯ | ◯ | 16.1 | 36.6 | ◯ | ◯ |
| Example 4 | Absence | ◯ | ◯ | 18.8 | 27.7 | ◯ | ◯ |
| Example 5 | Absence | ◯ | ◯ | 13.6 | 26.5 | ◯ | ◯ |
| Example 6 | Absence | ◯ | ◯ | 12.1 | 22.0 | ◯ | ◯ |
| Example 7 | Absence | ◯ | ◯ | 9.0 | 52.0 | ◯ | ◯ |
| Example 8 | Absence | ◯ | ◯ | 10.0 | 56.3 | ◯ | ◯ |
| Example 9 | Absence | ◯ | ◯ | 8.2 | 49.6 | ◯ | ◯ |
| Example 10 | Absence | ◯ | ◯ | 17.3 | 46.8 | ◯ | ◯ |
| Example 11 | Absence | ◯ | ◯ | 16.5 | 45.2 | ◯ | ◯ |
| Example 12 | Absence | ◯ | ◯ | 22.0 | 49.6 | ◯ | ◯ |
| Example 13 | Absence | X | ◯ | 19.3 | 50.2 | ◯ | ◯ |
| Example 14 | Absence | X | ◯ | 8.2 | 33.4 | ◯ | ◯ |
| Example 15 | Absence | Δ | ◯ | 7.3 | 28.6 | ◯ | ◯ |
| Example 16 | Absence | X | ◯ | 17.4 | 45.6 | ◯ | ◯ |
| Example 17 | Absence | Δ | ◯ | 16.3 | 44.3 | ◯ | ◯ |
| Comparative | Absence | ◯ | X | 8.3 | 15.4 | X | ◯ |
| Example 1 | | | | | | | |
| Comparative | Absence | X | X | 6.4 | 7.3 | X | Δ |
| Example 2 | | | | | | | |
| Comparative | Presence | — | Δ | 24.0 | 41.0 | ◯ | Δ |
| Example 3 | | | | | | | |
| Comparative | Absence | ◯ | Δ | 4.6 | 19.8 | X | X |
| Example 4 | | | | | | | |
| Comparative | Absence | ◯ | Δ | 3.6 | 21.6 | X | X |
| Example 5 | | | | | | | |
| Comparative | Absence | ◯ | X | 1.9 | 15.4 | X | Δ |
| Example 6 | | | | | | | |
| Comparative | Presence | — | ◯ | 23.6 | 46.5 | ◯ | Δ |
| Example 7 | | | | | | | |
| Comparative | Presence | — | Δ | 25.2 | 41.0 | ◯ | Δ |
| Example 8 | | | | | | | |
| Comparative | Absence | X | X | 1.5 | 15.3 | X | Δ |
| Example 9 | | | | | | | |
| Comparative | Absence | X | X | 4.7 | 5.3 | X | Δ |
| Example 10 | | | | | | | |

*the value of( ) is difference between surface energy of resist.

From Table 3, it was seen that the adhesive film of the present invention can be laminated on a back of a wafer at a temperature lower than a softening temperature of a protecting tape for an ultra-thin wafer, or a dicing tape to be laminated, can reduce a thermal stress such as warpage of a wafer, has no chip flight at dicing, has better picking up property, can simplify a step of manufacturing a semiconductor device, and is excellent in heat resistance and humidity resistance reliance.

According to the aforementioned present invention, there can be provided (1) a wafer back applying manner adhesive film which can reply to ultra-thin wafer utility or low temperature application at 100° C. or lower, (2) an adhesive sheet in which the aforementioned adhesive film and a UV-type dicing tape are applied, which can simplify the aforementioned applying step until a dicing step, (3) a adhesive film which can reduce a heating temperature when a adhesive film is heated to a melting point upon application of the adhesive sheet to a back of a wafer (hereinafter, referred to as laminate), below a softening temperature of the aforementioned UV-type dicing tape, and not only can improve workability, but also can solve a problem of warpage of a wafer which is greatly increased in a diameter and is thinned, (4) a adhesive film having heat resistance and humidity resistance which are required when a semiconductor chip having a great difference in a thermal expansion coefficient is packaged on a semiconductor-carrying support member, and excellent in workability, and low staining property, and (5) a semiconductor devise which can simplify a step of manufacturing a semiconductor device, and is excellent in reliance.

It would be understood by a person skilled in the art that the foregoing are preferable embodiments of the present invention, and many variations and modifications can be performed without departing the sprit and scope of the present invention.

What is claimed is:

1. In a method for fabricating a semiconductor device, the improvement comprising the steps of:
laminating an adhesive film layer of an integrated adhesive sheet on a back of a semiconductor wafer, at the temperature in a range of 10 to 80° C.;
dicing to obtain a semiconductor chip with the adhesive film attached thereto; and
adhering the semiconductor chip with the adhesive film to a semiconductor-carrying support member or to another semiconductor chip after picking up the semiconductor chip with the adhesive film, to obtain a semiconductor device,
wherein the integrated adhesive sheet is an adhesive film comprising: a substrate layer; a self-adhesive layer; and the adhesive film layer in this order, the adhesive film layer having a tan δ peak temperature of −20 to 60° C. and a flow amount of 100 to 1500 μm.

2. The method according to claim 1, wherein at a stage where the adhesive film layer is laminated to a semiconductor wafer at 80° C., a 90° peeling force at 25° C. to the semiconductor wafer is 5N/m or larger.

3. The method according to claim 1, wherein the self-adhesive layer is a radiation curing self-adhesive layer.

4. The method according to claim 1, wherein the step of adhering is performed by die-bonding under a condition of Tg (herein, tan δ peak temperature) of a film+100° C.×500 gf/chip×3 sec, and then heating and pressing under a condition of 180° C.×5 kgf/chip×90 sec.

5. The method according to claim 1, wherein said semiconductor wafer is a silicon wafer.

6. The method according to claim 5, wherein at a stage where the adhesive film layer is laminated to a silicon wafer at 80° C., a 90° peeling force at 25° C. to the silicon wafer is 5N/m or larger.

7. A semiconductor device having a structure in which at least one of (1) a semiconductor chip and a semiconductor-carrying support member, and (2) semiconductor chips, are adhered via an adhesive film that has an adhesive film layer,
wherein the adhesive film layer has a tan δ peak temperature of −20 to 60° C. and a flow amount of 100 to 1500 μm.

8. The semiconductor device according to claim 7, wherein the adhesive film layer of the adhesive film is in contact with and adhered to a semiconductor chip.
